(19) United States
(12) Patent Application Publication
(10) Pub. No.: US 2025/0200233 A1
(43) Pub. Date: Jun. 19, 2025

(54) BUILDING CODE CHECK PLUG-IN

(71) Applicant: University of Florida Research Foundation, Inc., Gainesville, FL (US)

(72) Inventors: Deepak Balakrishnan, Gainesville, FL (US); Nawari O. Nawari, Gainesville, FL (US); Ravi Shankar Srinivasan, Gainesville, FL (US)

(21) Appl. No.: 18/538,958

(22) Filed: Dec. 13, 2023

(51) Int. Cl. G06F 30/13; G06Q 50/16

(52) U.S. Cl. CPC G06F 30/13; G06Q 50/165

(57) ABSTRACT

The present disclosure presents systems and methods for integrating and executing a building code check tool. One such method comprises obtaining a construction model of a construction project, wherein the construction model includes construction project parameters; and obtaining an input specifying a regulatory building code section. The method further comprises performing a compliance code check against the regulatory building code section by capturing the construction model parameters from the construction model; prompting a user to provide additional construction model parameters; and evaluating the construction model against the regulatory building code section using the captured construction model parameters and the additional construction model parameters; and outputting a list of model elements, wherein a result of the compliance code check for a model element is indicated next to the model element, wherein selection of the model element causes a location of the model element to be displayed within the construction model.

### BACKGROUND

Building construction codes institute various requirements to be met by new construction projects. Thus, building codes often specify requirements to be met by building or infrastructure projects. Thus, to determine whether a project or design is compliant with these requirements, project parameters are needed to be obtained, calculated, and/or evaluated, such as, but not limited to, the type of construction, the insulation values, the size and type of windows, their location and orientation, etc. Accordingly, the skill and know-how required to obtain the appropriate design parameters can involve much effort, costs, and time in order to comply with the applicable government codes and laws.

### BRIEF DESCRIPTION OF THE DRAWINGS

The details of the present disclosure, both as to its structure and operation, may be gleaned in part by study of the accompanying drawings, in which like reference numerals refer to like parts.

FIG. 1 displays a block diagram of a building/infrastructure code check system in accordance with the present disclosure

FIG. 2 shows a building information model (BIM) viewer application that includes a plug-in component of a model code check interface tool in accordance with various embodiments of the present disclosure.

FIG. 3 shows panels of a model code check interface tool that includes a user account management panel, a building/infrastructure permit panel, and a building/infrastructure code check panel in accordance with various embodiments of the present disclosure.

FIG. 4 shows a display of additional graphical controls within the model code check interface tool after selection of the building/infrastructure permit management panel of FIG. 3.

FIG. 5 shows a display of a toolbar that includes graphical controls or panels directed to inputting administrative information and providing code chapters and related sections of a building/infrastructure code and includes additional panels comprising a sections panel, a code specific/results panel, and a family configurator panel in response to selection of the building/infrastructure code check panel of FIG. 3.

FIG. 6 shows a display of a user interface control that is configured to specify a scope of a project, a project type, and a building type in response to activating administrative features of the toolbar of FIG. 5.

FIG. 7 shows an input panel graphical control upon which a user can input requisite parameters addressed or cited in the applicable code sections launched by the toolbar of FIG. 5.

FIG. 8 shows a summary of results visible on a left side panel of an exemplary model code check interface tool in accordance with various embodiments of the present disclosure.

FIG. 9 shows results of a compliance code check for a BIM model within a user interface display in accordance with various embodiments of the present disclosure.

FIGS. 10-11 show a family configurator panel that is displayed in response to selection of the building/infrastructure code check panel of FIG. 3.

FIG. 12 shows a display of a toolbar under a model code check interface tool tab in response to selection of the building/infrastructure code check panel of FIG. 3, where a sections panel is one of the graphical control panels that can be activated from the toolbar in accordance with various embodiments of the present disclosure.

FIG. 13 shows a display of a toolbar under a model code check interface tool tab in response to selection of the building/infrastructure code check panel of FIG. 3, where a code specific/results panel is one of the graphical control panels that can be activated from the toolbar in accordance with various embodiments of the present disclosure.

FIG. 14 shows a ribbon panel or toolbar illustrating a first layer of optimized inputs of programmables and non-programmables input data in accordance with various embodiments of the present disclosure.

FIG. 15 shows a floating panel of building elements, types, and configurations that illustrates a second layer of optimized inputs of programmables and non-programmables input data in accordance with various embodiments of the present disclosure.

FIG. 16 shows a display of applicable code sections for a BIM model that illustrate a third layer of optimized inputs of programmables and non-programmables input data in accordance with various embodiments of the present disclosure.

FIGS. 17-19 show a display of interface controls for providing parameter values required for applicable code sections for a BIM model that illustrate a fourth layer of optimized inputs of programmables and non-programmables input data in accordance with various embodiments of the present disclosure.

FIG. 20 show an additional layer of optimized inputs of programmables and non-programmables input data in accordance with various embodiments of the present disclosure.

FIGS. 21-22 show a Building Planning section of the 2015 International Residential Code (IRC) that can be coded to indicate whether certain parameters value can be obtained automatically using the family configurator graphical control or can be obtained by prompting a user for the appropriate response (using an input configurator interface) in accordance with various embodiments of the present disclosure.

FIGS. 23-28 shows code sections of the 2015 IRC related to Foundations, Floors, Wall Construction, Wall Coverings, Roof-Ceiling Construction, Roof Assemblies, and Chimneys and Fireplaces that have been indicated to include Programmable and/or Non-Programmable parameters in accordance with various embodiments of the present disclosure.

FIGS. 29-50 show additional depictions of user interface elements of an embodiment of the model code check interface tool in accordance with the present disclosure.

### DETAILED DESCRIPTION

In an embodiment, systems, methods, and non-transitory computer-readable media are disclosed for integrating and executing a building/infrastructure code check tool for a building/infrastructure management environment. This application is applicable to all embodiments of International Residential Code (IRC) and International Building Code (IBC) and their variations as applicable to all U.S. States and Regions. In the examples presented herein, codes are related to building/infrastructure code involving the Florida Building Code Residential (FBCR). However, exemplary methods and systems of the present disclosure are applicable to non-building codes in general and International Residential Code (IRC) and International Building Code (IBC) and their variations as applicable to all U.S. States and Regions, and worldwide.

Many have reported the benefits of Building Information Models (BIM) in the AEC (Architecture, Engineering & Construction) industry and have indicated that BIM has improved collaboration, cost-savings, project time schedules, have enhanced communications and data exchanges between different domains, and also have aided in the whole life cycle of a building. A BIM model contains information about all the different components represented in the design model, such as materials and equipment. For example, clicking on a window in a BIM may display all of the information about that window's brand, material, dimensions, efficiency rating, glass options, finish options, life cycle, etc.

Thus, in accordance with systems and methods of the present disclosure, a model code check interface tool is presented to review a BIM model of a building or infrastructure and ingest parameters of the BIM model in order to evaluate a compliance of a BIM design against applicable codes and regulations. For any parameters or information that is not available via the BIM model, the model code check interface tool is configured to prompt a user to provide the missing information so that the BIM design can be evaluated. In accordance with various embodiments, certain parameters or information is expected to be obtainable from a BIM model and is referred to as programmable inputs, whereas certain parameters or information is not expected to be obtainable from a BIM model and is referred to as non-programmable inputs. For the purposes of this patent application, Programmables (P) are defined as those specific building/infrastructure code chapters and related sections that may be solved using data obtained directly from the BIM and/or manufacturers' data and/or web inputs and interfaces and/or Artificial Intelligence (AI)/Machine Learning (ML)-based processes and techniques. Non-Programmables (NP) are all others related to code chapters and sections that may not be solved via Programmables (P).

After reading this description, it will become apparent to one skilled in the art how to implement the various alternative embodiments and alternative applications described herein. However, although various embodiments are described herein, it is understood that these embodiments are presented by way of example and illustration only, and not limitation. As such, this detailed description of various embodiments should not be construed to limit the scope or breadth of the appended claims.

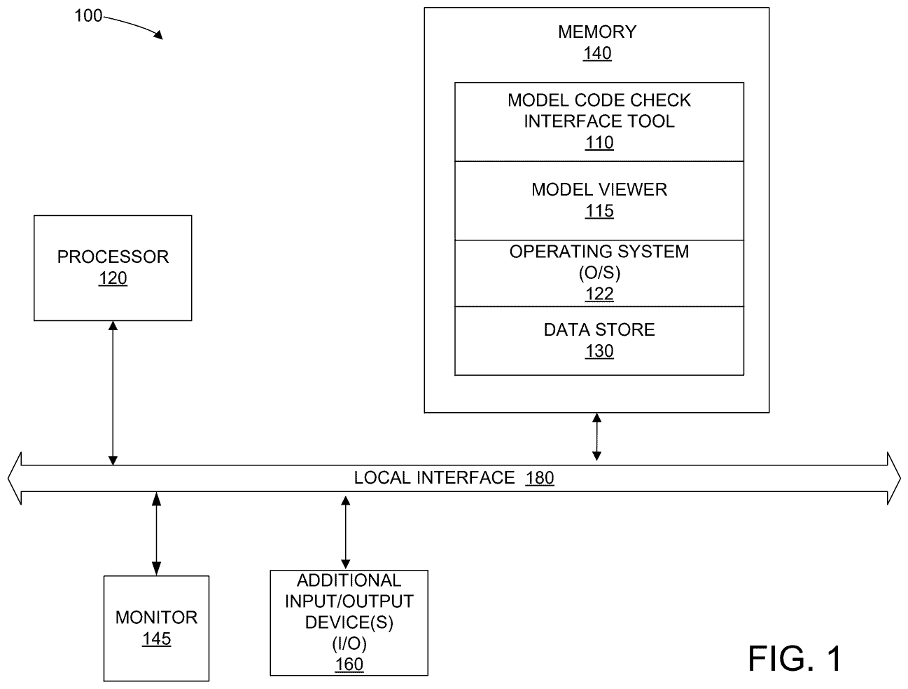

FIG. 1 displays a block diagram of a building/infrastructure code check system 100 in accordance with the present disclosure. The system 100 includes at least one processor 120, memory 140, a visual output device such as computer monitor 145, and one or more additional input and/or output (I/O) devices 160 (or peripherals) that are communicatively coupled via a local interface 180. These peripherals may be coupled to the processor 120 by electronic interfaces including input/output I/O ports, direct memory access (DMA) circuitry, registers, etc. which have not been included in the block diagram of FIG. 1 because such interfaces are well known to those skilled in the art.

According to an exemplary embodiment, the processor 120 is a hardware device for executing software, particularly that stored in memory 140. The processor 120 can be any custom made or commercially available processor, a central processing unit (CPU), an auxiliary processor among several processors associated with the display device 100, a semiconductor based microprocessor (in the form of a microchip or chip set), a macroprocessor, or generally any device for executing software instructions. Also stored in the memory 140 may be a data store 130 and other data, which stores information relevant to the model code check interface tool 110 or model viewer application 115, such as BIM models, input information, building code sections, manufacturer data, etc. The data store 130 can be located in a single installation or can be distributed among many different geographical or network locations.

The user may interact with the system 100 utilizing one or more user devices. A user device may comprise any device capable of communicating over a network and/or communicating content. For example, a user device may take the form of a computer or processor, or a set of computers/processors, such as a computer, laptop, notebook, hand held computer, personal digital assistant, cellular phone, smart phone (e.g., iPhone®, BlackBerry®, Android®, etc.), tablet, wearable (e.g., smart watch and smart glasses), automotive infotainment system, or any other suitable device having user interaction capabilities or dialog capabilities. The user device may be in electronic communication with the system 100 via a computer or communication network.

Processor(s) 120 may comprise a central processing unit (CPU). Additional processors may be provided, such as a graphics processing unit (GPU), an auxiliary processor to manage input/output, an auxiliary processor to perform floating-point mathematical operations, a special-purpose microprocessor having an architecture suitable for fast execution of signal-processing algorithms (e.g., digital-signal processor), a slave processor subordinate to the main processing system (e.g., back-end processor), an additional microprocessor or controller for dual or multiple processor systems, and/or a coprocessor. Such auxiliary processors may be discrete processors or may be integrated with processor 120. Examples of processors which may be used include, without limitation, the Pentium® processor, Core i7® processor, and Xeon® processor, all of which are available from Intel Corporation of Santa Clara, California.

The local interface or bus 180 can be, for example but not limited to, one or more buses or other wired or wireless connections, as those skilled in the art will appreciate. The local interface 180 may have additional elements, which are omitted for simplicity, such as controllers, buffers (caches), drivers, repeaters, and receivers, to enable communications. Further, the local interface may include address, control, and/or data connections to enable appropriate communications among the aforementioned components.

A model code check interface tool 110 of the present disclosure can be implemented in software (e.g., firmware), hardware, or a combination thereof. In one embodiment, the system is implemented in software, as an executable program, and is executed by a special or general purpose digital computer, such as a personal computer (PC; IBM-compatible, Apple-compatible, or otherwise), workstation, minicomputer, or mainframe computer. As such, the model code check interface tool 110, in some embodiments, is a source program, executable program (object code), script, or any other entity comprising a set of instructions to be performed. When a source program, then the program needs to be translated via a compiler, assembler, interpreter, or the like, which may or may not be included within the memory 140 so as to operate properly in connection with the O/S 122. Furthermore, the model code check interface tool 110 can be written as (a) an object oriented programming language, which has classes of data and methods, or (b) a procedure programming language, which has routines, subroutines, and/or functions, for example but not limited to, C, C++, C#, Objective C, Java®, JavaScript®, Perl, PHP, Visual Basic®, Python®, Ruby, Flash®, or other programming languages. In accordance with the present disclosure, the model code check interface tool 110 may reside within storage on a local device or remotely accessible across a network.

In some embodiments, the model code check interface tool 110 is implemented in software and may be implemented as an auxiliary “plug-in” (also referred to as an “add-in”) or “widget” which affects the display of documents generated by another program or application. For example, in such an approach, the model code check interface tool may perform an evaluation of compliance of a BIM design against applicable codes and regulations. Additionally, in some embodiments, the model code check interface tool 110 may be incorporated into a software application, such as a model viewer application 115 (e.g., Autodesk Revit application, CAD model viewer program (e.g., AutoCAD), etc.), where the software application renders a building information model of a building or infrastructure design having one or more parameters that can be ingested by the model code check interface tool and used to check compliance of the building information model against applicable codes and regulations.

In various embodiments, the model code check interface tool 110 for performing a building/infrastructure code check is overlaid on a model viewer application 115 in the form of Autodesk Revit® software. In other embodiments, the model code check interface tool 110 may be overlaid/integrated with other applications, such as Computer-Aided Design (CAD), Building Information Modeling (BIM), and/or any other independent and/or web-based software tools and/or web-based interfaces or applications. In some embodiments, the model code check interface tool software shows a semi-transparent interface embedded with buttons for enabling the above listed actions. This interface is moveable (rotate, move, translate, scale) and can be pinned to the software program. In various embodiments, the model code check interface tool 110 can be web components, that is, available via the web which can directly interface with the Model viewer application(s), including Autodesk® web-based tools and applications including Autodesk® Forge, Autodesk® BIM360, etc. In some embodiments, the software can run in the cloud-computing environment or in a desktop application.

Thus, in some embodiments, the model code check interface tool 110 comprises a plug-in or add-in piece of software for an existing computer program. In some embodiments, the plug-in software installed as an external program (also referred to as “addin”) allows the user of the software program to (a) perform real time code checking and/or compliance of individual building and site elements or components of the building information model as the model is being developed/modeled in the software platform; (b) perform real time code checking and/or compliance of whole site as the site design model is being developed/modeled in the software platform; (c) perform real time display of relevant codes for individual site elements or components as the site design model is being developed/modeled in the software platform; (d) perform real time display of relevant codes for the whole site as the site design model is being developed/modeled in the software platform; and (d) perform real time display and interactive training materials or site elements or components or whole site as the site design model is being developed/modeled in the software platform. In some embodiments, the plug-in software shows a semi-transparent interface embedded with buttons for enabling the above listed actions. This interface is moveable (rotate, move, translate, scale) and can be integrated within the software program. In some embodiments, the plug-in software can run in the cloud-computing environment or in a desktop application.

In various embodiments, the model code check interface tool 110 may comprise a web application that runs on a web server and is usually accessed through a web browser. Web applications can be developed without considering cross-platform computer operating systems because they run on web servers and the users can access the applications provided via the internet. Web application frameworks are usually used to support the development of web applications, including web services, web resources and web APIs. Examples of web application frameworks include, e.g., Ruby on Rails, Django, Angular, Express, Spring, etc.

In embodiments in which a web service is provided, model code check interface tool 110 and/or model viewer application 115 may receive requests and provide responses in extensible Markup Language (XML), JavaScript Object Notation (JSON), and/or any other suitable or desired format. In such embodiments, model code check interface tool 110 and/or Model viewer application 115 may provide an application programming interface (API) which defines the manner in which external system(s) may interact with the web service and rely on the web service to implement or otherwise provide backend processes, methods, functionality, storage, and/or the like.

If the building/infrastructure code check system 100 is a PC, workstation, personal digital assistant, or the like, the software in the memory 140 may further include a basic input output system (BIOS) (omitted for simplicity). The BIOS is a set of essential software routines that initialize and test hardware at startup, start the O/S 122, and support the transfer of data among the hardware devices. The BIOS is stored in ROM so that the BIOS can be executed when the display device 110 is activated.

The memory 140 can include any one or combination of volatile memory elements (e.g., random access memory (RAM, such as DRAM, SRAM, SDRAM, etc.)) and nonvolatile memory elements (e.g., ROM, hard drive, tape, CDROM, etc.). Moreover, the memory 140 may incorporate electronic, magnetic, optical, and/or other types of storage media. Note that the memory 140 can have a distributed architecture, where various components are situated remote from one another, but can be accessed by the processor 120.

The software in memory 140 may include one or more separate programs, each of which comprises an ordered listing of executable instructions for implementing logical functions. In the example of FIG. 1, the software in the memory 140 includes the model code check interface tool 110 in accordance with the present disclosure, a model viewer application 115, and a suitable operating system (O/S) 122. A nonexhaustive list of examples of suitable commercially available operating systems 122 is as follows: (a) a Windows operating system available from Microsoft Corporation; (b) a Macintosh operating system available from Apple Computer, Inc.; (c) a UNIX operating system, which is available for purchase from many vendors, such as the Hewlett-Packard Company, Sun Microsystems, Inc., and AT&T Corporation; (d) a LINUX operating system, which is freeware that is readily available on the Internet; or (e) an appliance-based operating system, such as that implemented in handheld computers, mobile phones, or tablets. The operating system 122 essentially controls the execution of other computer programs, such as the model code check interface tool 110, and provides scheduling, input-output control, file and data management, memory management, and communication control and related services.

The I/O devices 160 may include input devices, for example but not limited to, a keyboard, mouse, scanner, microphone, etc. Furthermore, the I/O devices 160 may also include output devices, for example but not limited to, a printer, display, etc. Finally, the I/O devices 160 may further include devices that communicate both inputs and outputs, for instance but not limited to, a modulator/demodulator (modem; for accessing another device, system, or network), a radio frequency (RF) or other transceiver, a telephonic interface, a bridge, a router, etc. One input device 160 of the present disclosure includes a keyboard and an electro-mechanical or optical mouse. The input device 160 can be used to input information which is acted upon by the processor 120 to control a cursor or other pointer on a computer display, such as a computer monitor 145. Other pointer mechanisms such as trackballs, electronic pens, input tablets, joystick, touch pad, arrow keyboard controls, etc. are considered to be equivalents of the mouse.

The monitor 145 is coupled to the processor 120 and includes a screen upon which an image can be displayed. Among others, the monitor 145 may be a raster-type device (such as a video monitor or a liquid-crystal display panel) having a matrix of picture elements or “pixels” which can be selectably activated to create the image.

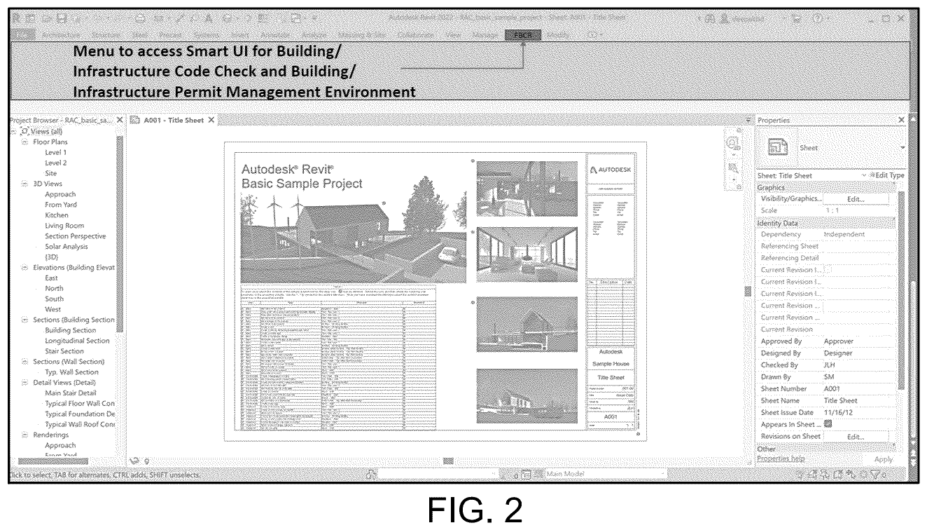

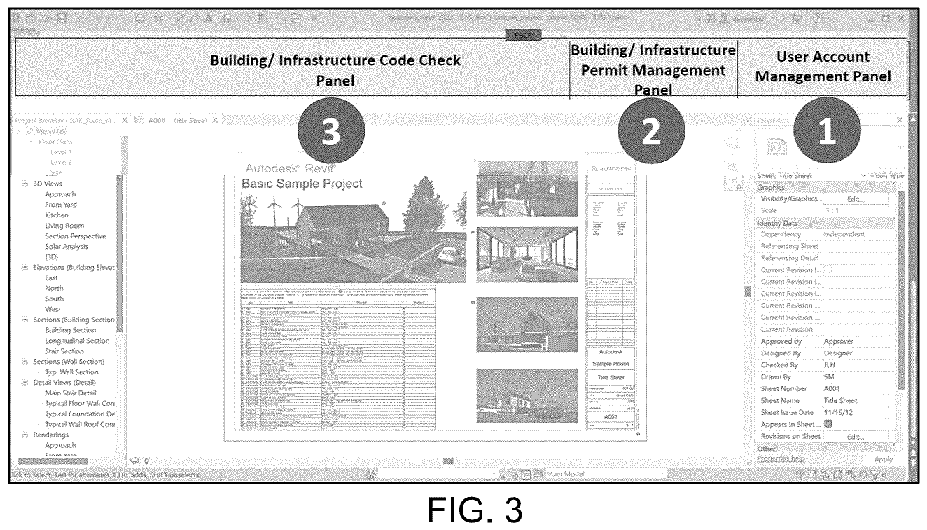

Referring now to FIG. 2, shown is a screenshot of a Model viewer application, namely an Autodesk Revit interface that also includes an plug-in component of the model code check interface tool 110. In the example of FIG. 2, a graphical ribbon element of the model viewer application includes a selectable tab for the model code check interface tool (that is labeled “FBCR” in this non-limiting example). Accordingly, upon selecting the model code check interface tool tab, a toolbar is displayed under the tab that includes option panels to access a user account (also referred to as a user account management panel), to access the model code check interface tool (that is referred to as a “Smart UI” in this non-limiting example) for a BIM model (for a building or infrastructure design) that can obtain requisite input parameters from the BIM model and/or prompt the user to provide requisite input parameters, to perform a compliance code check for the BIM model based on the requisite input parameters (also referred to as a building/infrastructure code check panel), and to prepare building permit applications or forms based on the requisite input parameters (also referred to as a building/infrastructure permit management panel). As represented in FIG. 3, the panels of the model code check interface tool can include a user account management panel 1, a building/infrastructure permit management panel 2, and a building/infrastructure code check panel 3 that are located on various positions within a display screen as required by the user. A user preference to move the panels is allowed such that a panel on a left side of the display can be repositioned to the right side of the display and vice versa.

Via the user account management panel 1, a user can input a username and password or can reset a previous password input by the user. Additionally, the user can configure a user profile or account information, input billing or address information, access help and support materials or contacts, watch training materials, etc.

Via the building/infrastructure permit management panel 2, a user can input a state/region and/or country whose building codes or regulations are to be used during application of the model code check interface tool. Thus, after the state/region and/or country is selected, relevant code sections for the selected area are activated to be used with the model code check interface tool 110 when performing code compliance checks or preparing certain forms or permit applications, as a non-limiting example.

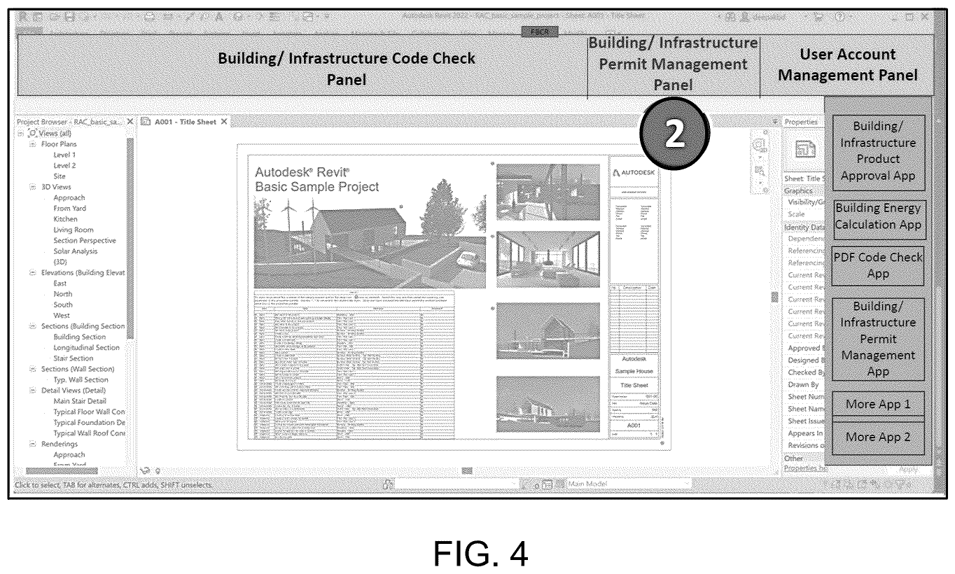

Additionally, as represented in FIG. 4, selection of the building/infrastructure permit management panel 2 can cause additional graphical controls to be shown (under the tab) that include a graphical control or button to launch a building/infrastructure product approval app (application), a graphical control to launch a building energy calculation app, a graphical control to launch a PDF Code Check App, a graphical control to launch a Building/Infrastructure Permit Management App, and graphical controls for launching other applications.

In various embodiments, the building/infrastructure product approval app relates to a software application that is designed for checking/validating Florida Product Approval form submitted during permit process (Florida product approval are required by Florida Statute 553.842 and Florida Administrative Code 61G20-3). Product Approval application is designed to reduce human errors, the time and effort required to manually check the product approval numbers and identify errors before submission for permit. Also, it can be used by permit officials and CBOs to check the product approval sheet.

In various embodiments, the building energy calculation app relates to a software application that is designed for checking/validating form R405 generated by commercial software applications.

In various embodiments, the PDF Code Check App relates to a software application that is designed for checking/validating general notes in construction documents during permit process. General Notes PDF to Code Check application is designed to reduce human errors, the time and effort required to manually check general notes and identify corresponding sections in Florida Building Code Residential (FBCR) and identify errors before submission for permit. This application is applicable to all embodiments of International Residential Code (IRC) and International Building Code (IBC) and their variations as applicable to all U.S. States and Regions. Also, it can be used by permit officials and CBOs to check the product approval sheet.

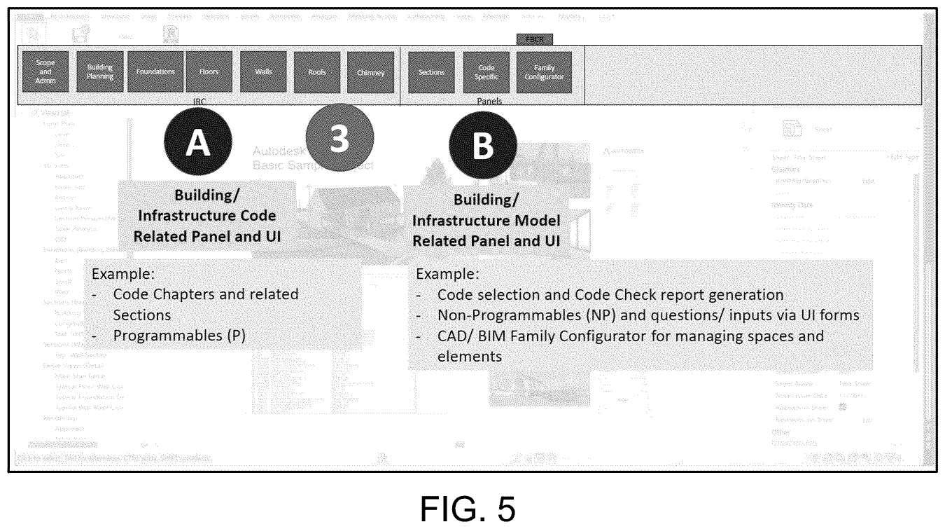

As represented in FIG. 5, selection of the building/infrastructure code check panel 3 can cause a graphical toolbar to be displayed under the model code check interface tool tab (“FBCR” in FIG. 5) that includes graphical controls or panels (A) directed to inputting building information and providing code chapters and related sections of the building/infrastructure code of the inputted state/country (e.g., Florida, United States), such as “Scope and Admin,” “Building Planning,” “Foundations,” “Floors,” “Walls,” “Roofs,” “Chimney,” etc. Additional graphical control panels (B) can also be provided, such as a sections panel, a code specific/results panel, and a family configurator panel.

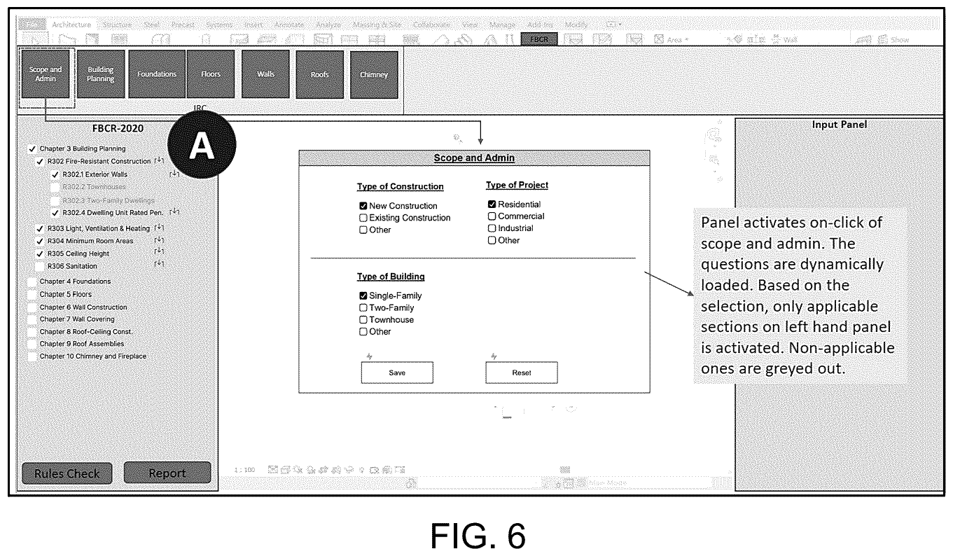

As represented in FIG. 6, selection of the scope and admin control activates a user interface control or box that is configured to specify a scope of a project, such as whether the project is a new construction, an existing construction, or other type of construction; is configured to specify a project type, such as whether the project is residential, commercial, industrial, or another type of project; and is configured to specify a type of building that is subject of the project, such as whether the building is a single-family dwelling, a two-family dwelling, a townhouse, or another type. The prompts and/or questions presented by the user interface control or box are dynamically loaded. Based on the selection, only applicable sections on left hand panel is activated. Non-applicable ones are grayed out.

In various embodiments, selection of the scope and admin control also activates a left hand panel (as a non-limiting example) that displays code sections that are applicable to the selected options from the user interface control. In particular, the applicable code sections are activated and designated with checkmarks and/or are in bold, whereas non-applicable code sections are grayed out, as represented in FIG. 6.

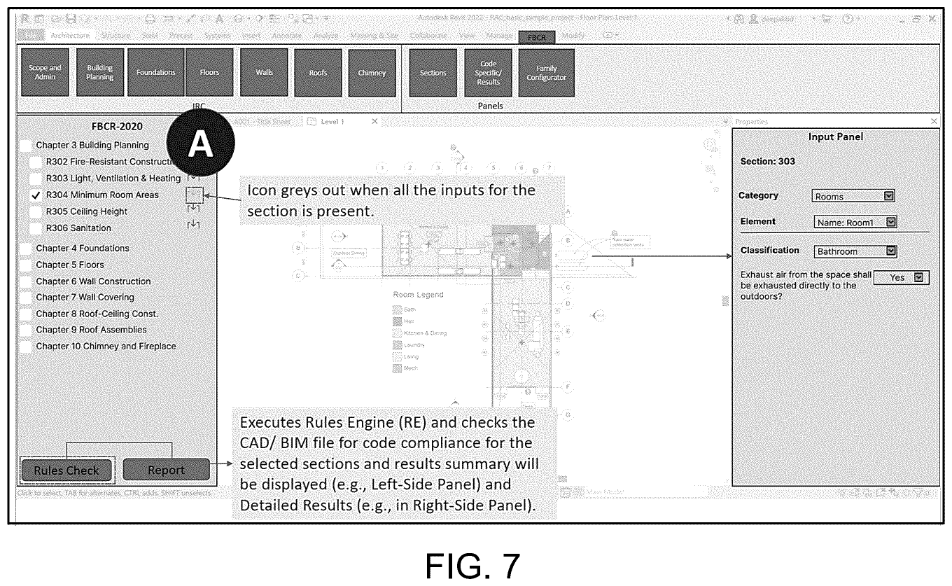

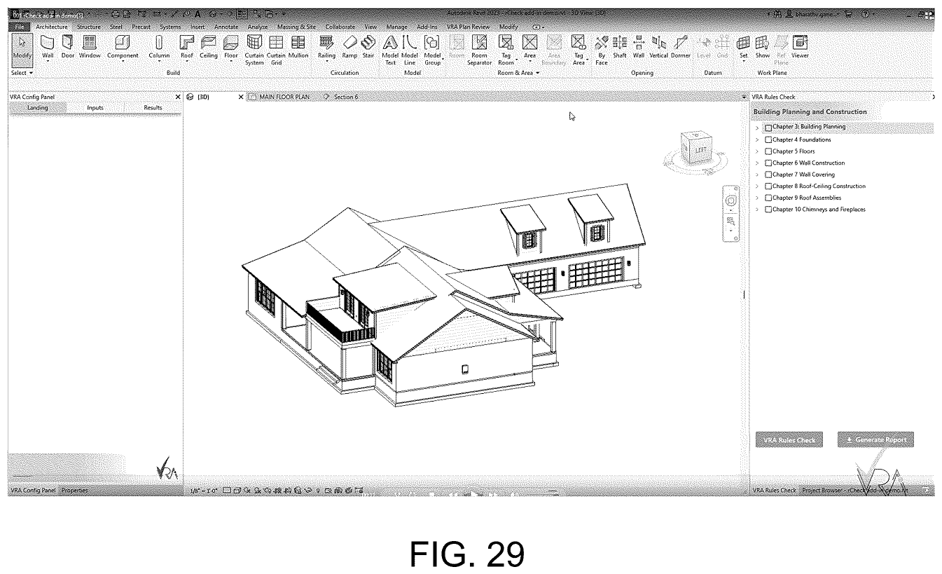

In various embodiments, selection of the scope and admin control further activates a right hand panel (as a non-limiting example) that provides a configurator input panel graphical control upon which a user can input requisite parameters addressed or cited in the applicable code sections provided in the left hand panel. For example, as shown in FIG. 7, the configurator panel provides dropdown boxes to specify parameter values required under code section 303 (of the 2020 Florida Building Code Residential section). These particular parameters are not specified in the building information model (BIM) that has been opened in the model viewer application 115 that is visible in the behind the model code check interface tool controls (e.g., right hand configurator panel and left hand code section panel). The placement of the respective panels can be moved or stacked according to user's preferences. For example, FIG. 29 shows an exemplary implementation of the model code check interface tool 110 with the configurator panel on the left and the code section panel on the right.

In the example of FIG. 7, a user has specified that one of the rooms in the BIM model is a bathroom that does exhaust air directly to the outdoors which are required parameters to be used in determining if the BIM design is compliant with the requirements of Section R304 (Minimum Room Areas) as shown in the left hand panel control. As indicated, when all of the required information has been input by the user (e.g., non-programmable input parameters) and/or has been obtained from the BIM model itself (e.g., programmable input parameters), an “input” icon is grayed out next to the selected code section. Otherwise, if the input icon is not grayed out, additional input information is needed in order to determine if the BIM model is in compliance with the particular code section. Accordingly, after the input information is provided, a Rules Check option can be selected to execute a rules engine (RE) that is configured to check the BIM file for code compliance for the selected sections and a results summary will be displayed (e.g., as a left side panel). For a detail output of the results, a Report option can be selected, whereby a detailed report of the results can be displayed (e.g., displayed as a right side panel).

Thus, in various embodiments, for non-programmable input data (NP), user interface (UI)-based forms are displayed and dynamically populated based on the data that the user needs to input. This then is used to check for code compliance.

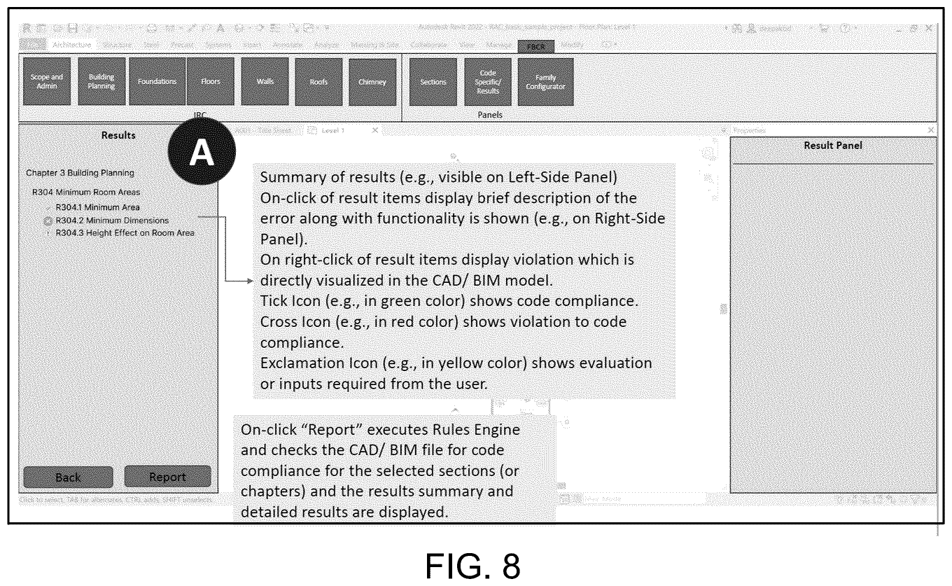

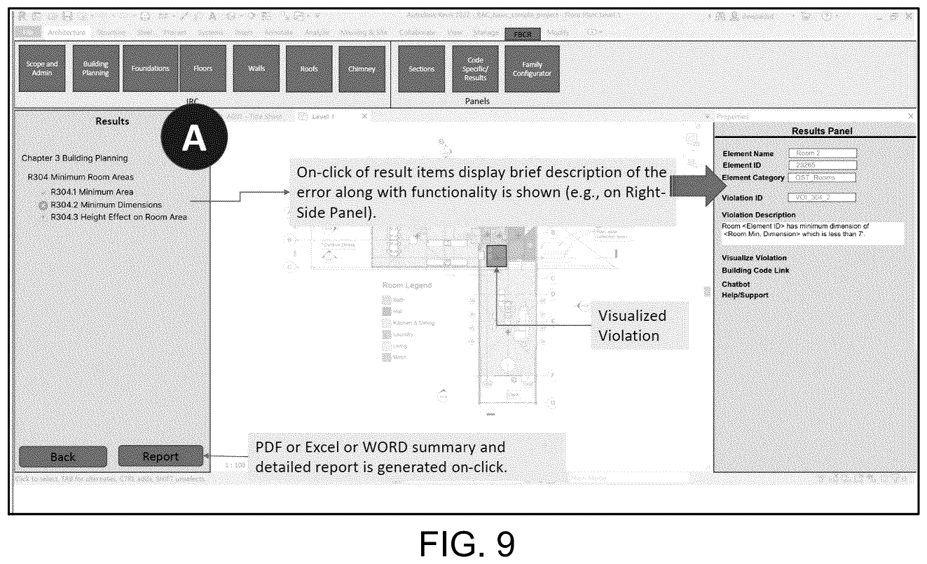

Referring now to FIG. 8, a summary of results is illustrated in a non-limiting example, where the summary is visible on a left side panel of the model code check interface tool 110. For example, the summary may list the applicable code sections/sub-sections that were checked against the BIM model and may also display an icon (or other graphical representation) indicating whether the model complied with requirements of the code section. In the example of FIG. 8, a checkmark or tick icon is used to indicate that the model complies with code section R304.1, an X or cross icon is used to indicate that the model does not comply with (i.e. violates) code section R304.2, and an exclamation icon is used to indicate that additional user information is needed before the compliance check can be completed for the model. For the code sections that are not indicated to be in compliance, the code section can be selected in the left side panel which causes a brief description of the error to be shown on a right side panel of the model code check interface tool 110, as shown in FIG. 9. Additionally, in various embodiments, selection of a non-compliant code section may cause a portion of the BIM model to be shown that is in violation of the applicable code section or is in need of additional information/input parameter(s) before the compliance check can be completed, as shown in FIG. 9. A copy of the summary report or the detailed report can be generated by selecting the Report option element, as illustrated in FIG. 9, where the Report option is illustrated as being in a left side control panel of the model code check interface tool 110 (in this non-limiting example). After the additional information is added or after the model is modified to address the listed error/violation, then the compliance check may be performed again or repeated.

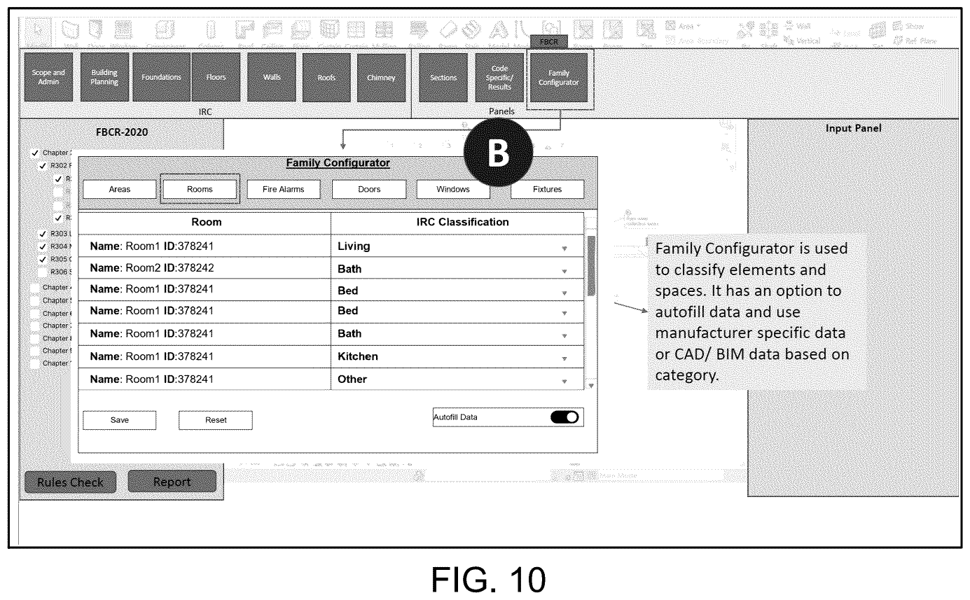

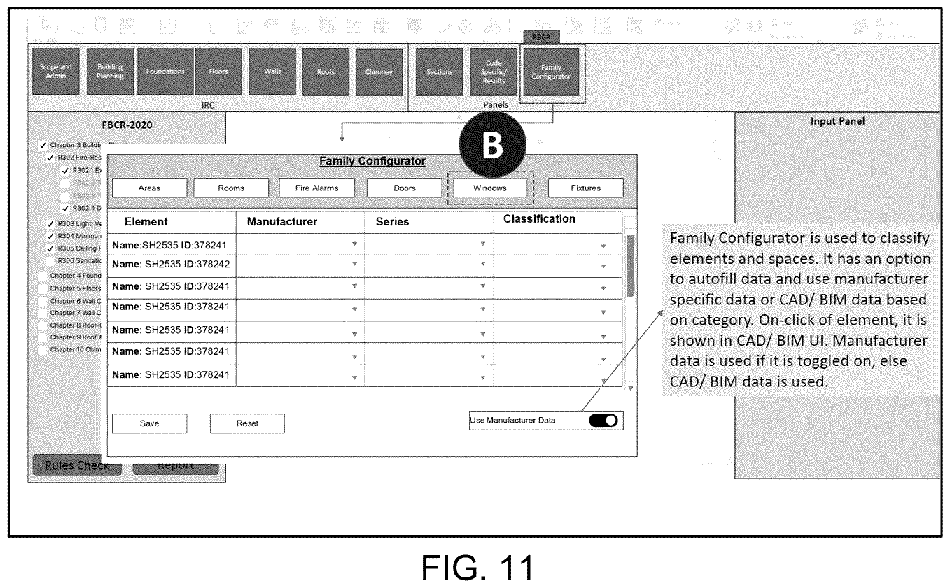

Referring back to FIG. 5, selection of the building/infrastructure code check panel 3 can cause a toolbar to be displayed under the model code check interface tool tab, where a family configurator panel is one of the graphical control panels that can be activated from the toolbar, as illustrated in FIG. 10. Activation or selection of the family configurator panel causes a family configurator user interface control or box to be displayed, where the family configurator control can be used to classify elements and spaces of the BIM model. For example, in various embodiments, the family configurator control has an option to autofill data and use manufacturer specific data (e.g., obtained from a remote server or database over the Internet or obtained from data store 130 of manufacturer specific data) or BIM data (from the BIM model) based on a category that can be designated by selecting one of a plurality of category options that are viewable within the family configurator control. Such data that is capable of being autofilled and populated by the family configurator control is also referred to as programmable data in the present disclosure. In various embodiments, a toggle control is provided on the family configurator control in order to select between using data from the BIM model or using manufacturer specific data. Accordingly, FIG. 10 shows the toggle control being set to use “Autofill Data” acquired from the BIM model and FIG. 11 shows the toggle control being set to “Use Manufacturer Data.”

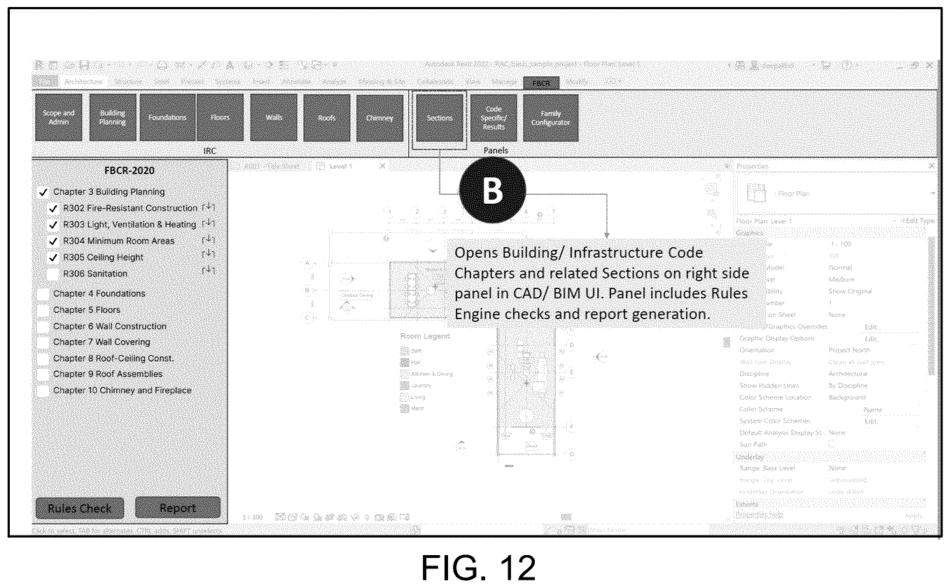

Referring again to FIG. 5, selection of the building/infrastructure code check panel 3 can cause a toolbar to be displayed under the model code check interface tool tab, where a sections panel is one of the graphical control panels that can be activated from the toolbar, as illustrated in FIG. 12. Selection of the sections panel causes a right side panel to be displayed with building and infrastructure code chapters and sections that are available for browsing by the user. The particular building and infrastructure code provisions that are displayed will be selected based on the country and state that the user previously inputted using the scope and admin panel of the model code check interface tool 110.

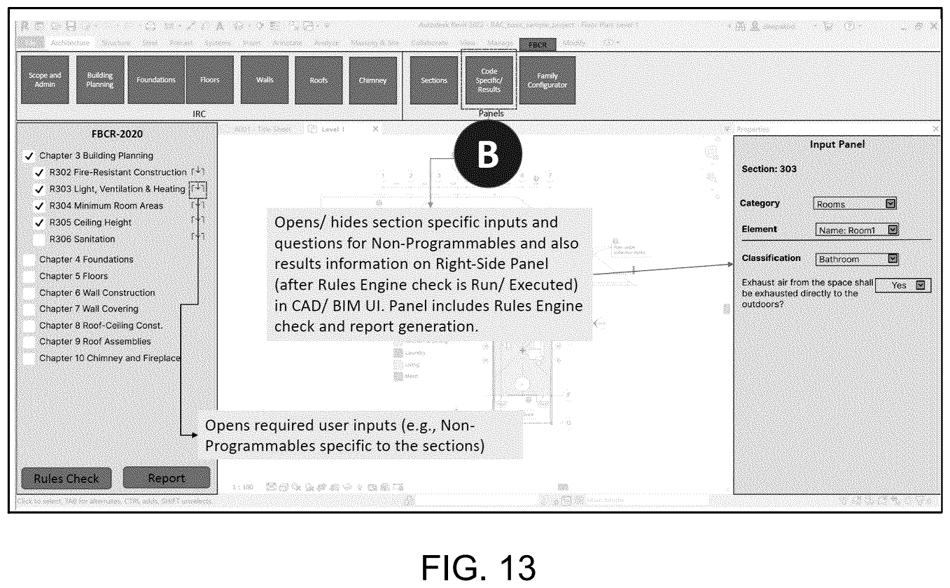

Referring again to FIG. 5, selection of the building/infrastructure code check panel 3 can cause a toolbar to be displayed under the model code check interface tool tab, where a code specific/results panel is one of the graphical control panels that can be activated from the toolbar, as illustrated in FIG. 13. Here, activation of the code specific/results panel causes an input configurator panel to be opened in a right side panel of the model code check interface tool 110. In an exemplary implementation, the configurator panel provides dropdown boxes having non-programmable parameter values for specified prompts or questions, such as a classification value for a certain room of the BIM model (e.g., The classification for Room1 is Bathroom) or an answer to a question (e.g., Yes for the question, “Exhaust air from space shall be exhausted directly to the outdoors?”). The configurator panel is provided for applicable code sections or provisions that are missing parameter values that are needed to determine if the BIM model is in compliance with the applicable code section. For example, in various embodiments, a left side panel shows the applicable code sections or provisions for the opened BIM model, where an input icon next a particular code section indicates if additional information is needed (e.g., when the input icon is not grayed out, then additional information is needed).

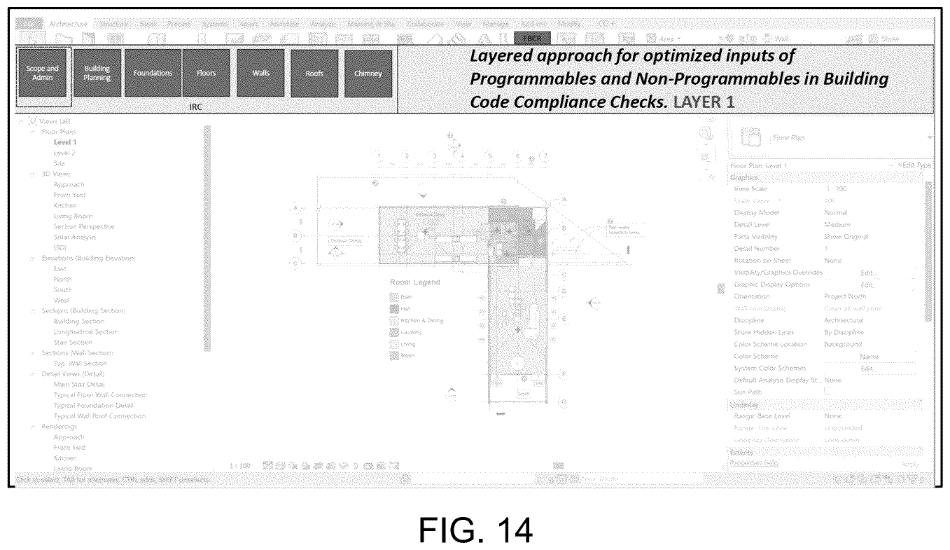

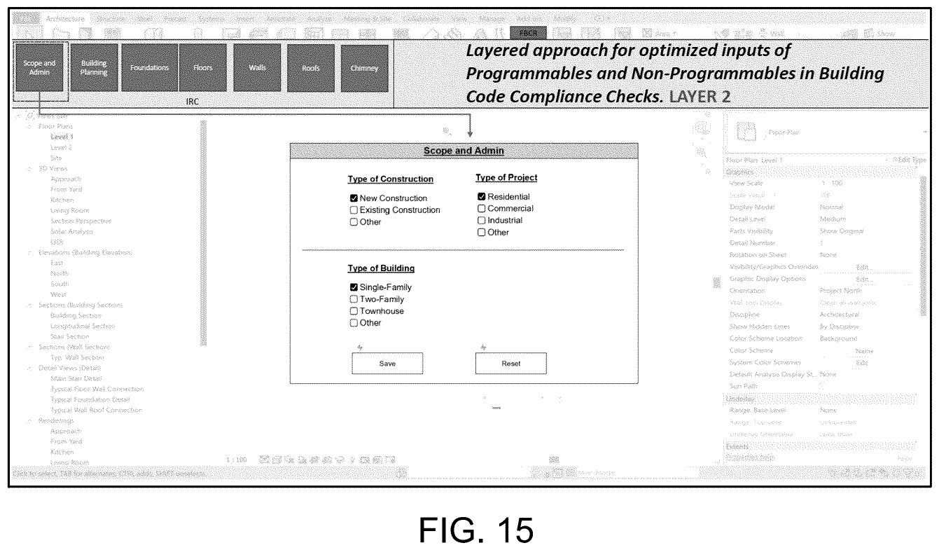

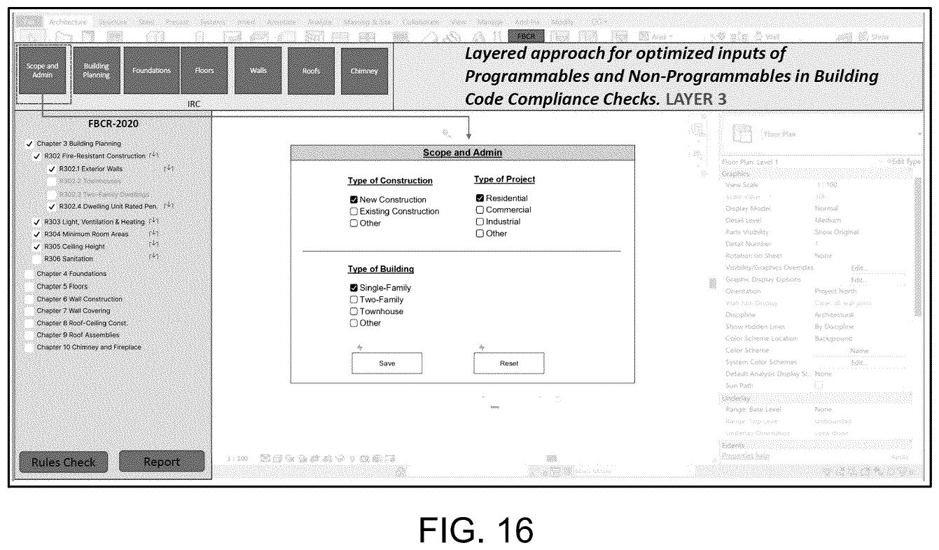

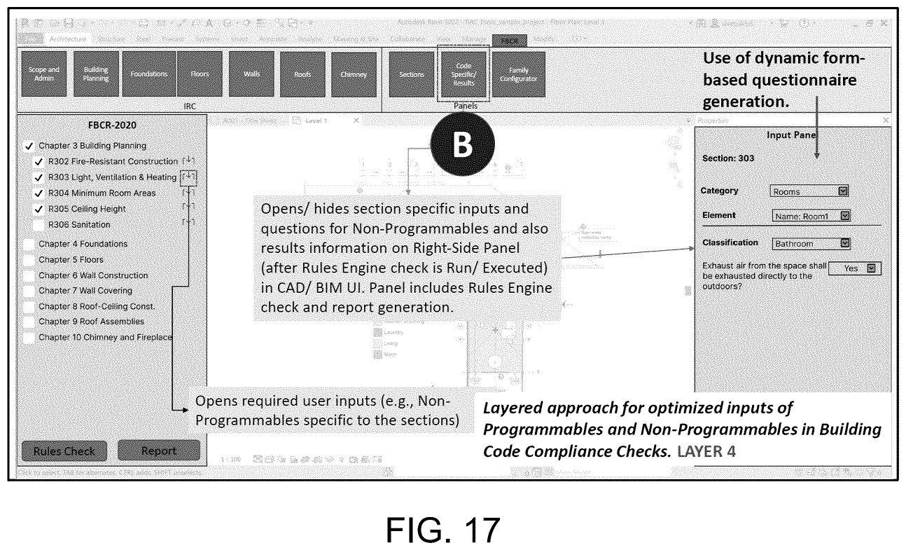

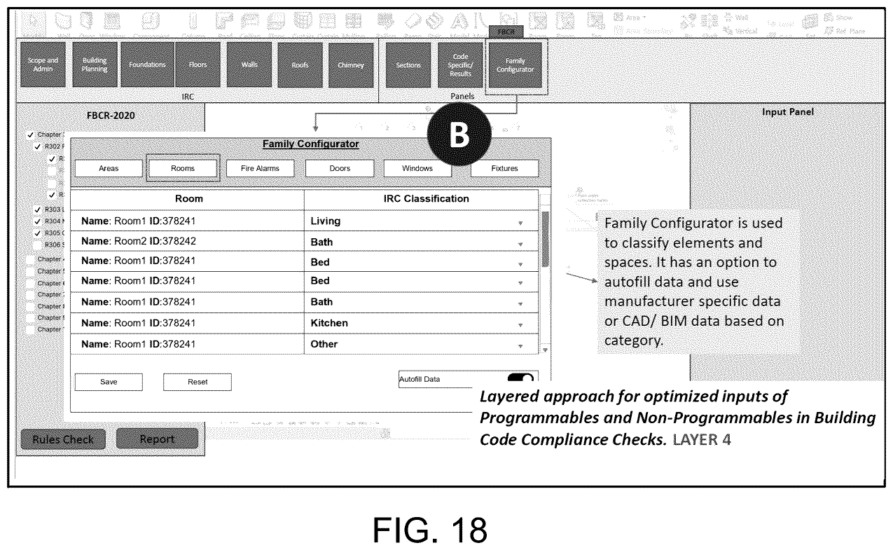

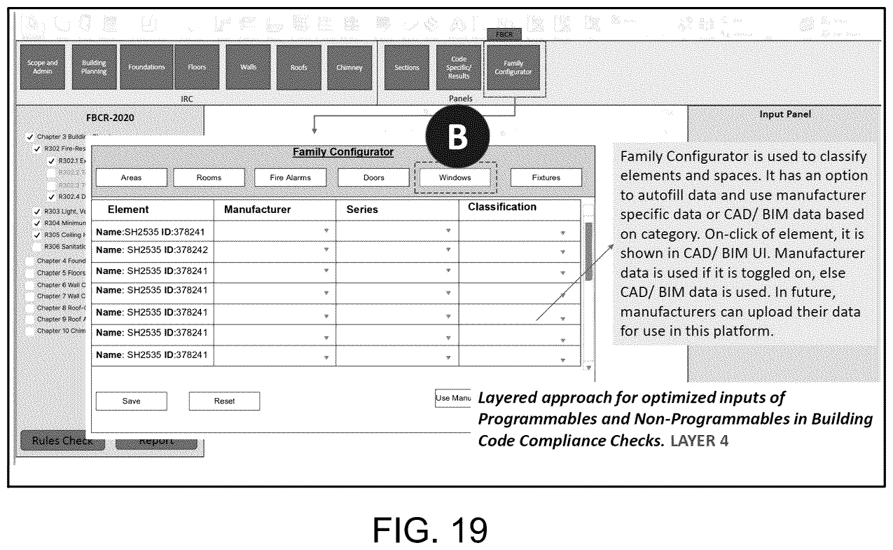

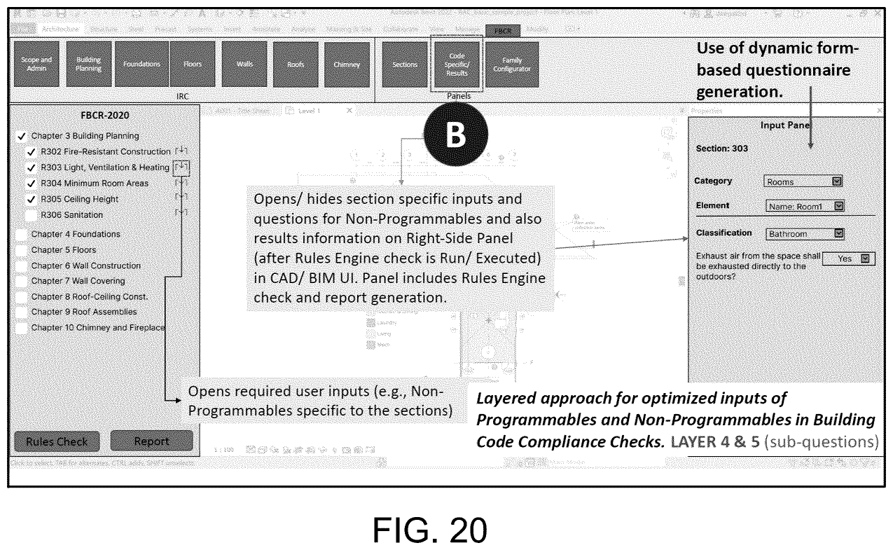

As demonstrated, an exemplary model code check interface tool 110 of present disclosure provides a layered approach for optimized inputs of programmables and non-programmables input data in building/infrastructure code compliance checks. In a first layer (Layer 1), a ribbon panel or toolbar is presented with panels showing chapters and major building components, as illustrated in FIG. 5 and FIG. 14. A second layer (Layer 2) provides a floating panel of building elements, types, and configurations that is configured to be displayed over a Model viewer application 115, as illustrated in FIG. 6 and FIG. 15. A third layer (Layer 3) presents or indicates the applicable code sections for a BIM model, where not-applicable code sections are grayed out in a left side panel, as illustrated in FIG. 7 and FIG. 16. A fourth layer (Layer 4) presents interface controls to provide parameter values required for applicable code sections for the BIM model, such as by clicking a non-grayed out input icon next to a code section. For example, a dynamically generated user interface control in a right side panel is presented or displayed to prompt a user to provide missing non-programmable parameter values, as illustrated in FIG. 7 and FIG. 17. Conversely, programmable parameter values can be previously provided via a family configurator control that automatically populates parameter values using manufacturer supplied information or BIM model information, as illustrated in FIGS. 10-11 and FIGS. 18-19. Additional layers (e.g., Layer 5) of user interface controls may also be presented to provide parameter input values for sub-questions/prompts on a right side panel as needed, as illustrated in FIG. 20.

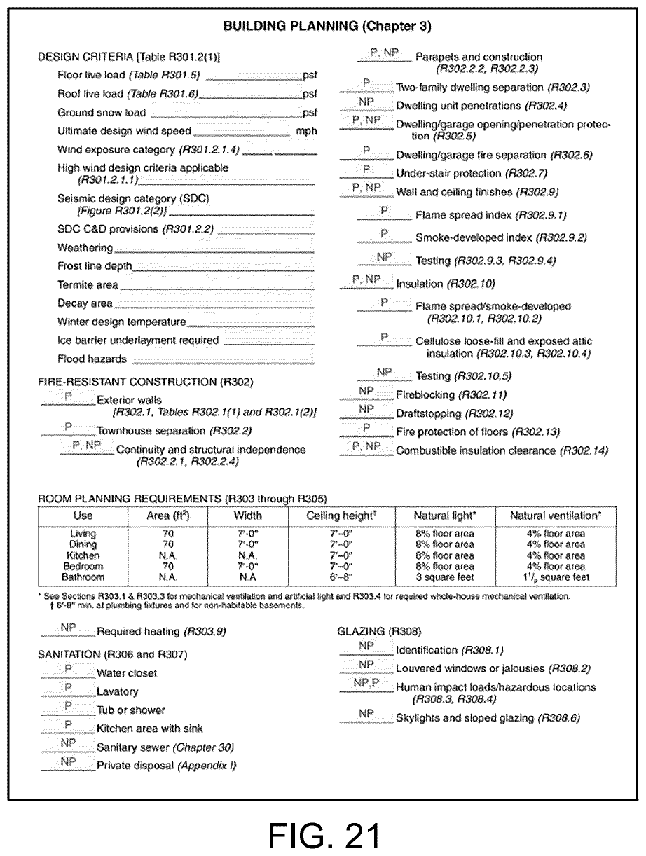

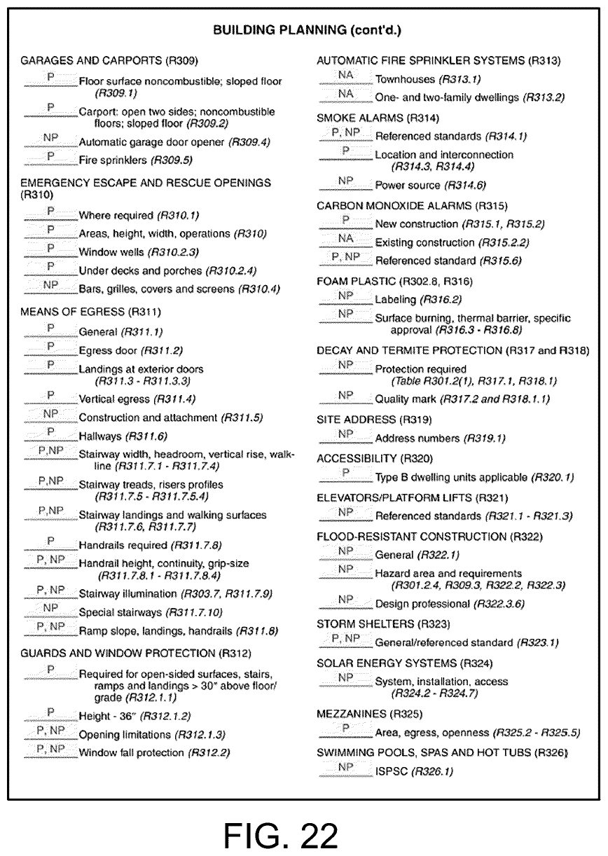

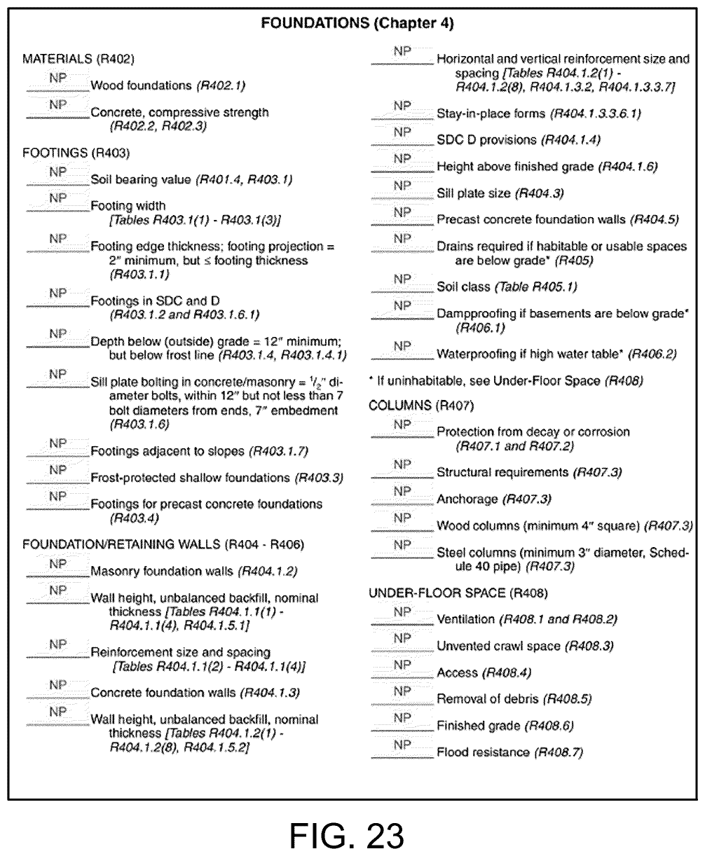

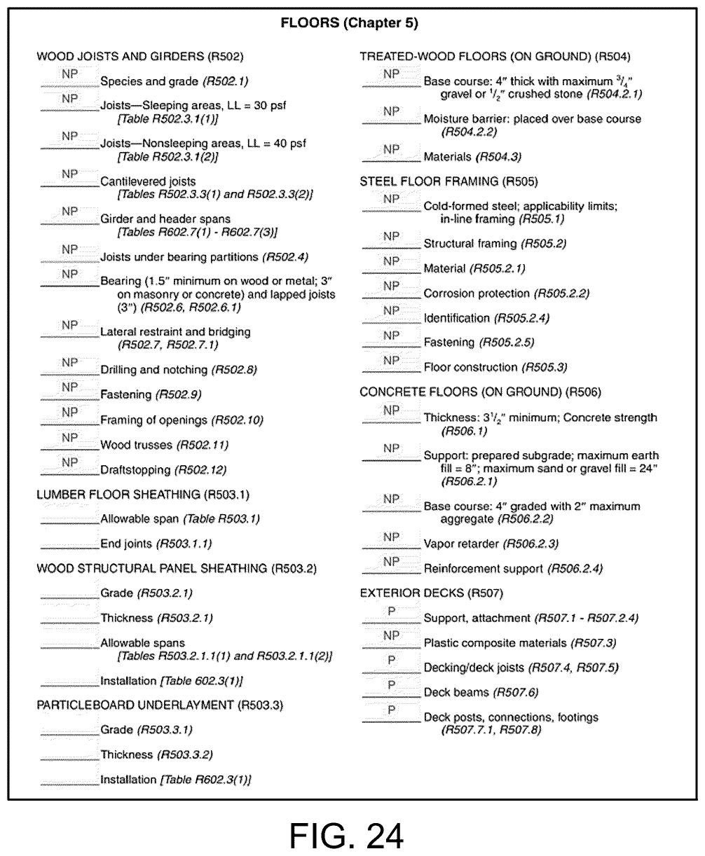

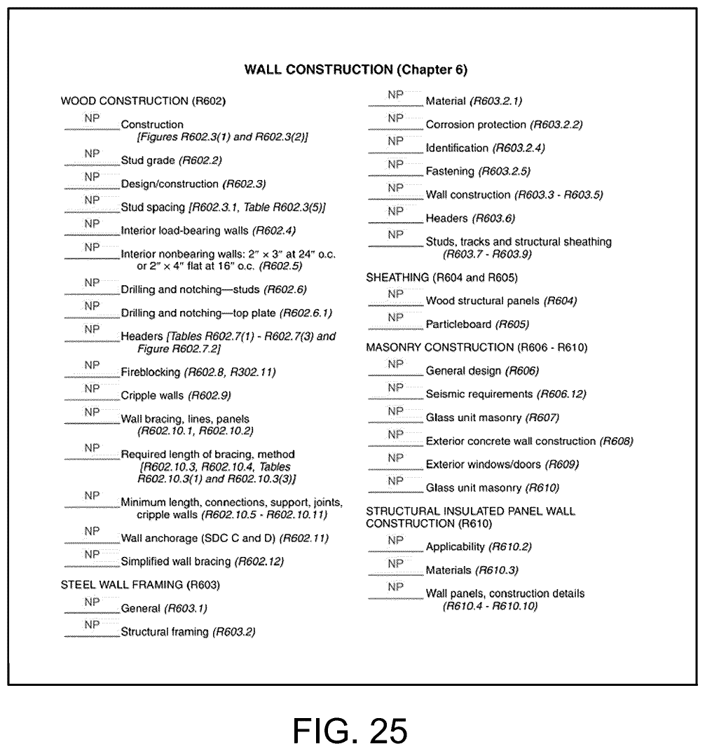

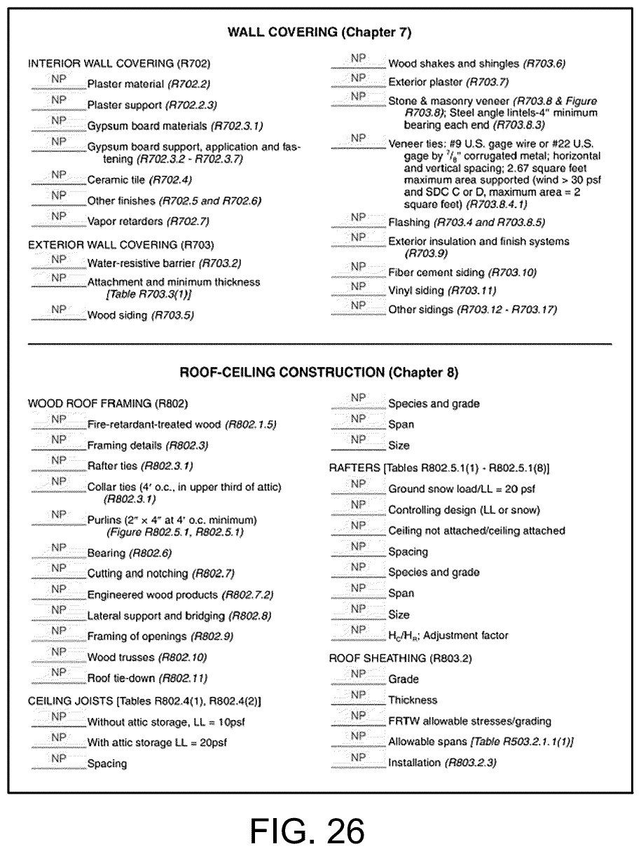

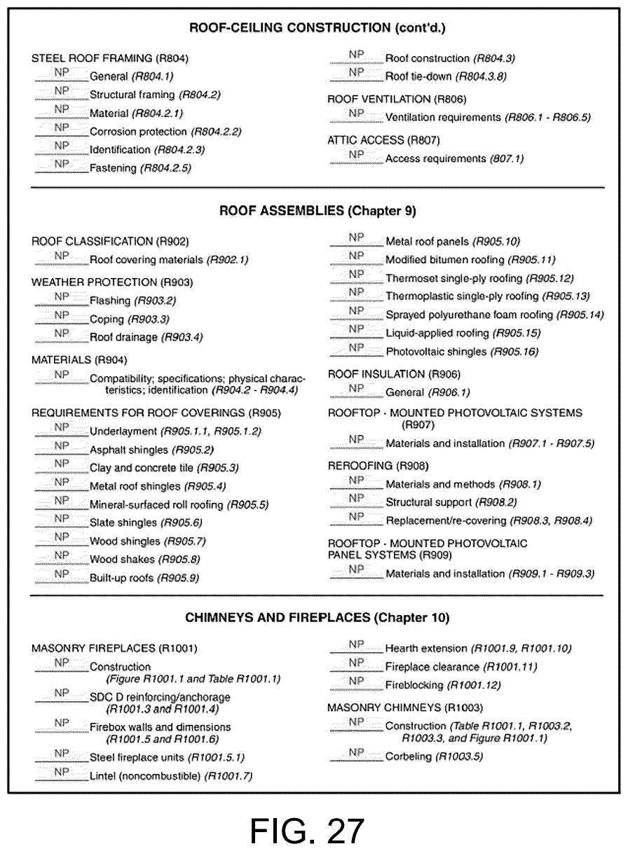

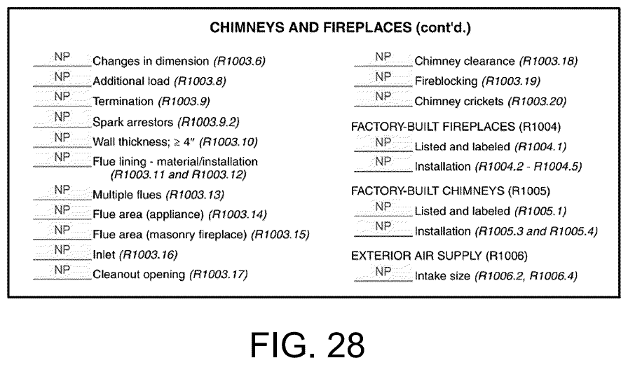

In accordance with various embodiments, certain parameters or information is expected to be obtainable from a BIM model and is referred to as programmable inputs, whereas certain parameters or information is not expected to be obtainable from a BIM model and is referred to as non-programmable inputs. To demonstrate, FIGS. 21-22 show an index of a Building Planning section of the 2015 International Residential Code (IRC) for one and two family plan review record, where certain sub-sections and provisions (e.g., Exterior Walls under Fire-Resistant Construction sub-section) are designated as requiring Programmable (P) parameters and/or Non-Programmable (NP) parameters. Accordingly, such code provisions can be coded to indicate whether certain parameters value can be obtained automatically using the family configurator graphical control or can be obtained by prompting a user for the appropriate response (using an input configurator interface). Similarly, FIGS. 23-28 shows other code sections of the 2015 IRC related to Foundations, Floors, Wall Construction, Wall Coverings, Roof-Ceiling Construction, Roof Assemblies, and Chimneys and Fireplaces that have been indicated to include Programmable and/or Non-Programmable parameters.

Referring now to FIGS. 29-50, additional depictions of an embodiment of the model code check interface tool 100 is presented. Here, in FIG. 29, the code section panel is on the right (in this non-limiting example) and includes a list of various chapters and sections listed in the Florida Building Code Residential provisions. A user can select sections and sub-sections that they wish to test and check a BIM model's compliancy with the FBCR with respect to those sections.

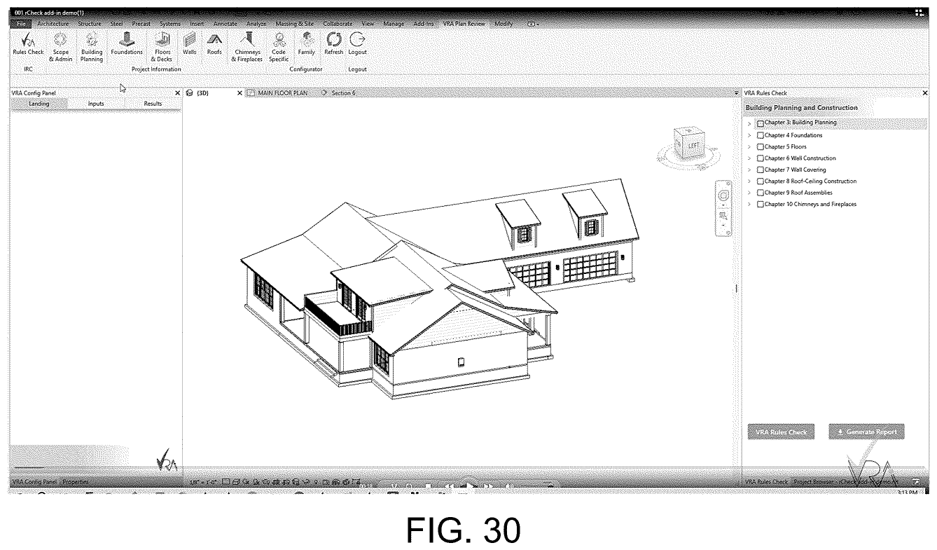

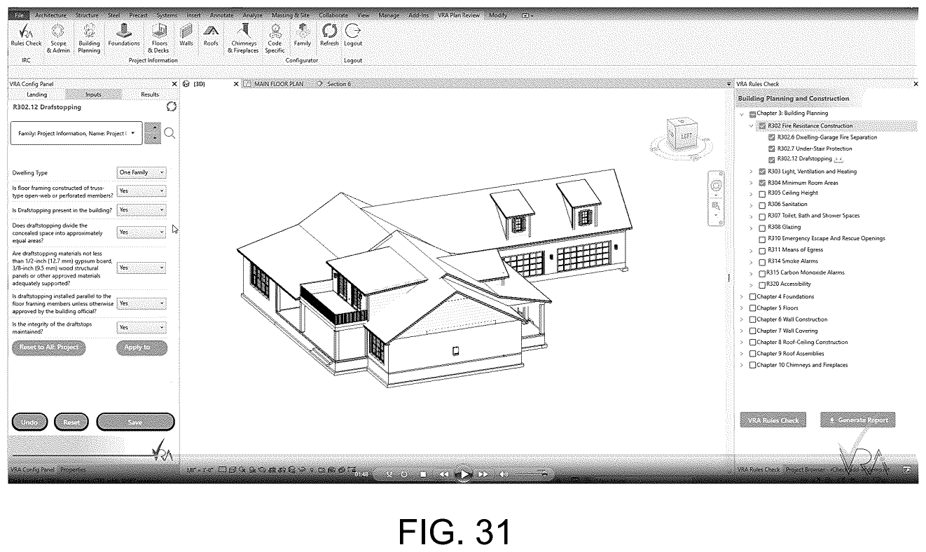

If the user cannot find a particular panel when they open the model code check interface tool add-in or plug-in (by selecting model code check interface tool tab (“VRA Plan Review” tab in FIG. 29 in this non-limiting example) or if the user closes the panel by mistake, the user can open the panel by selecting the Rules Check panel (shown in FIG. 30). The input configuration panel on the left (“VRA Config Panel” in FIG. 31 in this non-limiting example) is where the user can see the necessary inputs that their BIM model needs to run a specific section. If the user cannot find the panel, or if the user closes the panel by mistake, the user can open it by selecting the code specific ribbon in the Configurator panel on the toolbar (as shown in FIG. 31). If the input configurator panel is empty, the user has not yet selected any code sections and thus there are not any inputs needed at that time. To see the inputs, the user can select a code section or a subsection on the right side panel of FIG. 31 (in this non-limiting example). After which, an input icon may be displayed next to the selected code section(s) or sub-section(s). If the user clicks or selects the input icon, the needed inputs are displayed on the left side panel (in this non-limiting example). In some cases, the input icon may be grayed out and in some cases, it may not be grayed out. If the input icon is grayed out, this indicates that certain inputs are needed to be provided by the user before a compliance check is performed for that particular section. In certain cases, the input icon is not displayed next to a selected code section or sub-section which indicates that all the necessary information to test compliance of that section has been provided by the BIM model data itself.

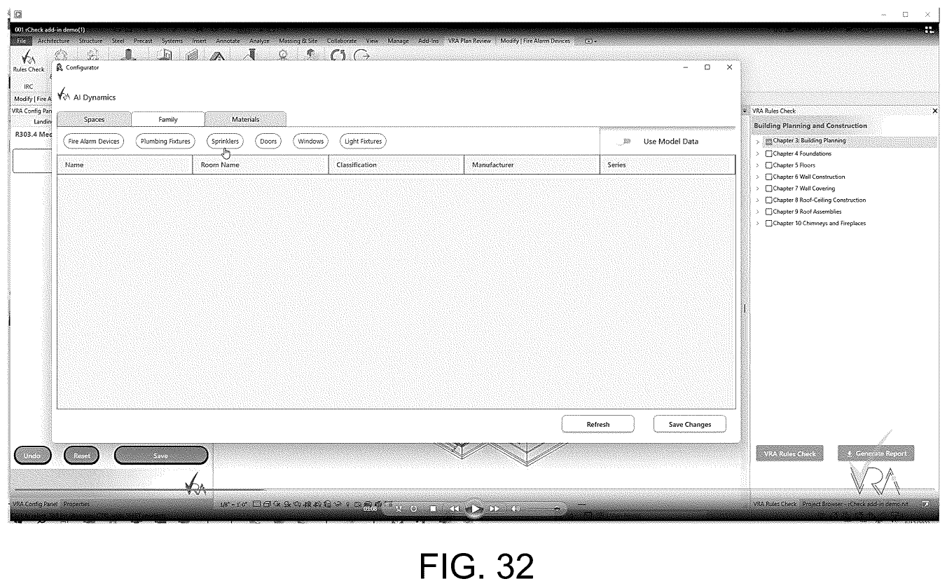

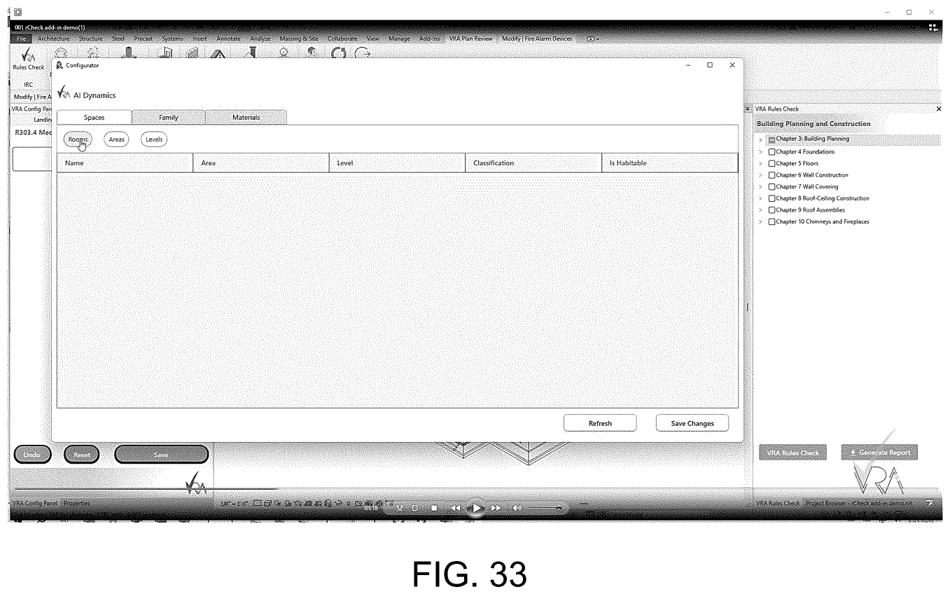

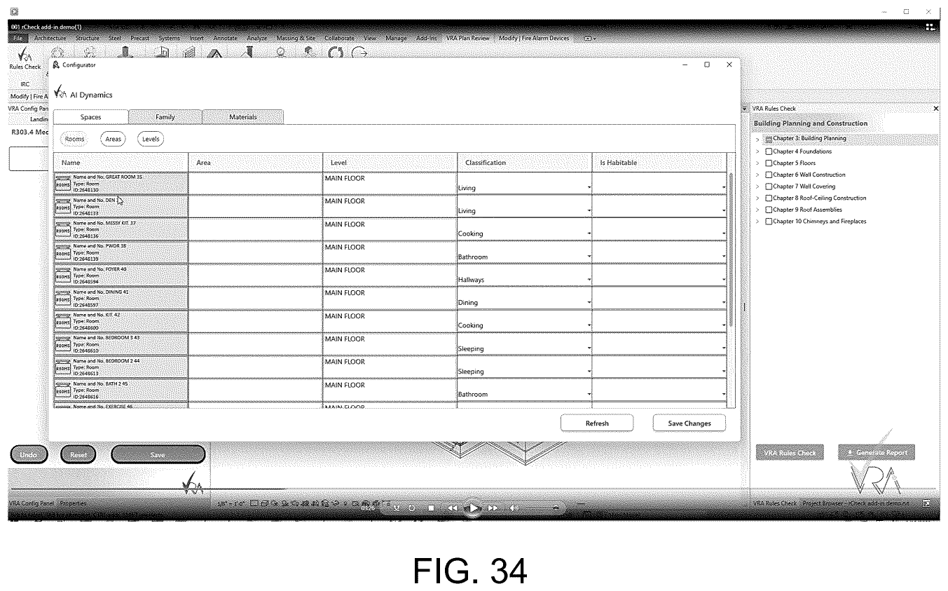

As shown in FIG. 32, an exemplary family configurator control includes a plurality of tabs that group building components. In the example of FIG. 32, the tabs are labeled spaces, family, and materials. Selection of the family tab presents a list of all the families (groupings of fixtures and devices) used in the model. In the example of FIG. 32, the families include Fire Alarm Devices, Plumbing Fixtures, Sprinklers, Doors, Windows, and Light Fixtures. Selection of the Spaces tab presents one or more spaces groups/types present in the model. In the example of FIG. 33, the Spaces group include Rooms, Areas, and Levels. The Room option may be used to classify the rooms based on the code section (e.g., FBCR) classification. As represented in FIG. 34, under the rooms option, a list of all the rooms present in the model are displayed with the rooms being classified according to the code section space classification based on the text information provided in the respective room tags. As shown, the “Great Room” is classified as “Living,” the “Messy Kit” is classified as “Cooking” and so on. Thus, a user need not manually classify the rooms as it is taken care by the model code check interface tool 110. Instead, all the user has to do is provide appropriate room names in the room tag associated with a building information model.

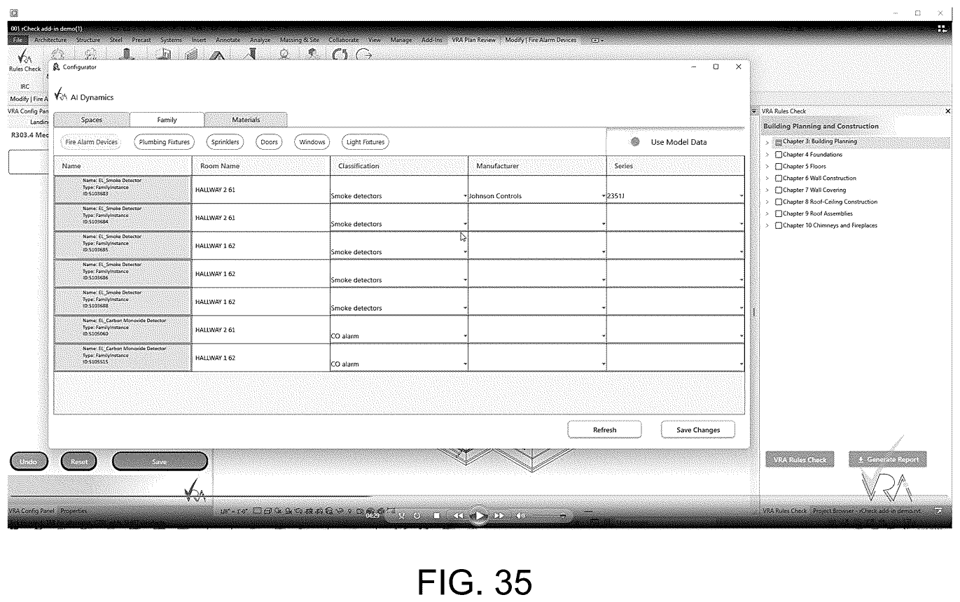

Similarly under the family space, various family types are present in the model, such as fire alarm devices, plumbing fixtures, sprinklers, doors, windows, light fixtures, etc. Upon selecting one of the family types, (e.g., Fire Alarm Devices), the model code check interface tool 110 lists out all the families present in the model under the selected type, as represented in FIG. 35. Here, a user can assign manufacturer details of the families which can be used to capture manufacture data when this feature is activated, such as by enabling the Use Model Data toggle in FIG. 35. Thus, even if a user personally knows those details or not, the use model data option can be used to extract information from the model. For example, since Revit families store only a defined amount of information and certain information has to be extracted from the manufacturer, such as glazing width or glazing thickness, this information may not be present in the model and has to be captured from the manufacturer. So, if a user assigns the correct manufacturer details to these families, the model code check interface tool 110 can capture a large amount of information useful for a compliance code check.

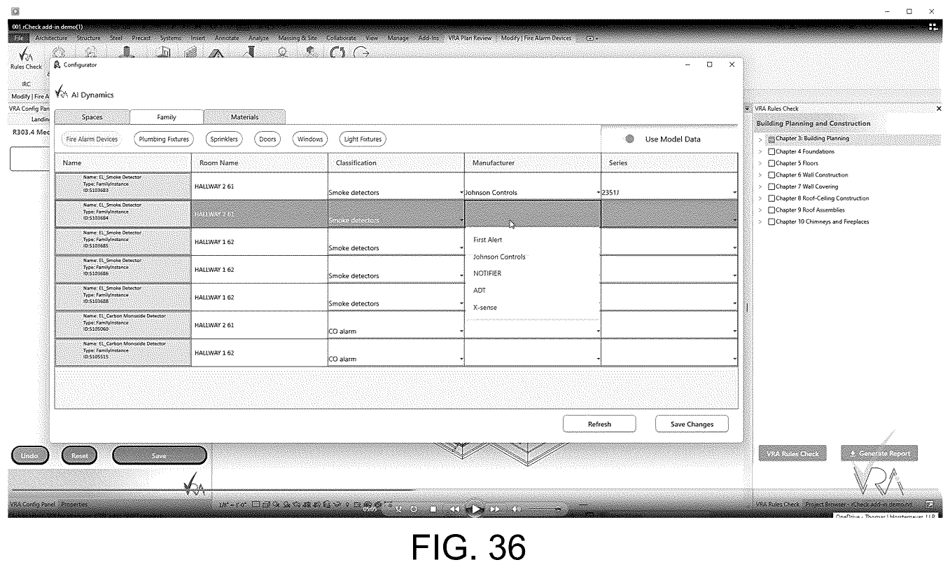

To assign the manufacturer details, a user can identify a particular family and select the correct manufacturer and series number from a drop down menu, as illustrated in FIG. 36. Correspondingly, in various embodiments, a data store 130 of the model code check interface tool 110 has a list of manufacturers present in the U.S. for any particular family. Therefore, in order to identify a model element associated with any family, its name can be displayed on a left column of the family configurator and a corresponding family can be displayed to its right on the family configurator (in a non-limiting example).

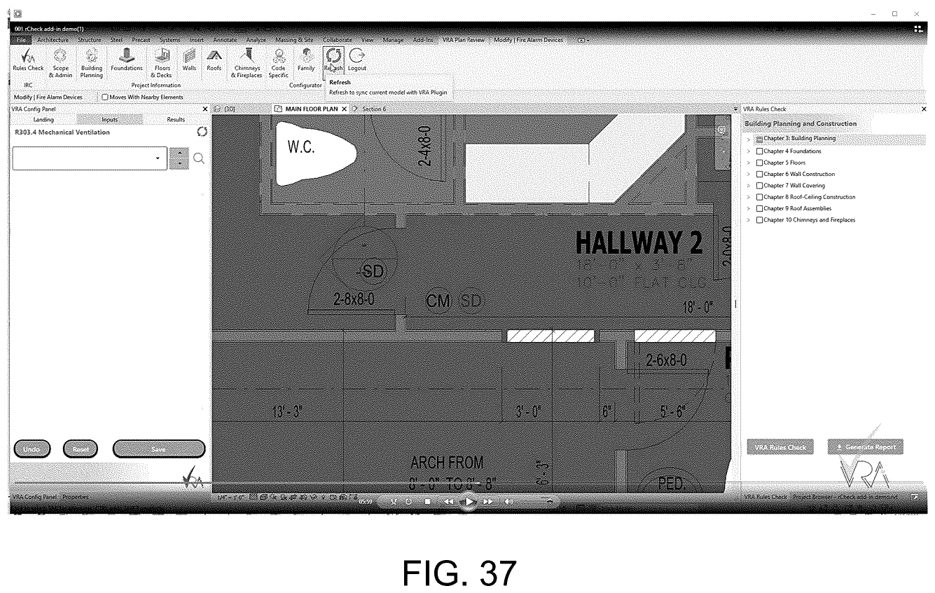

If the user makes any changes to the model, like creating or deleting elements or modifying any element, the model can be refreshed by selecting a Refresh control button or panel, as shown in FIG. 37.

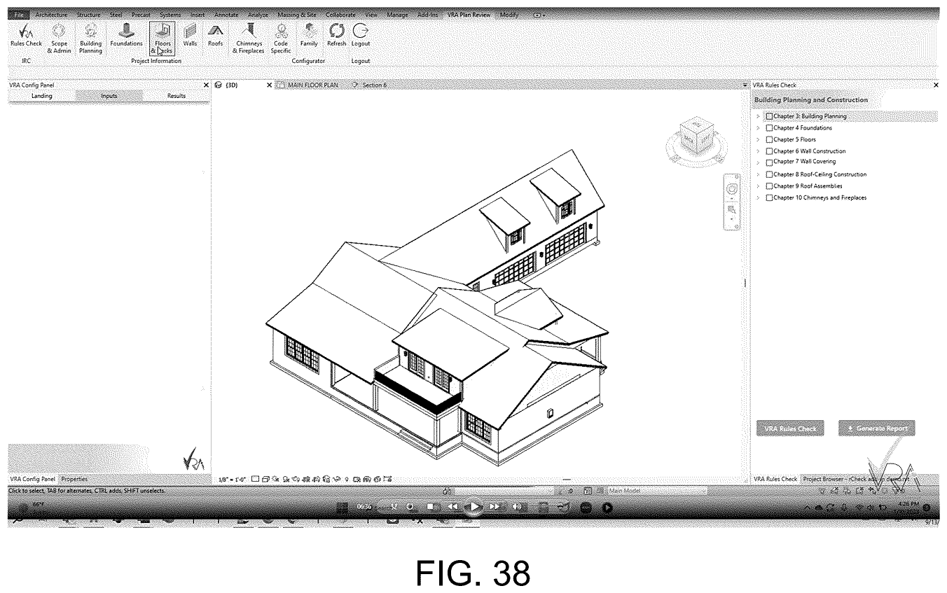

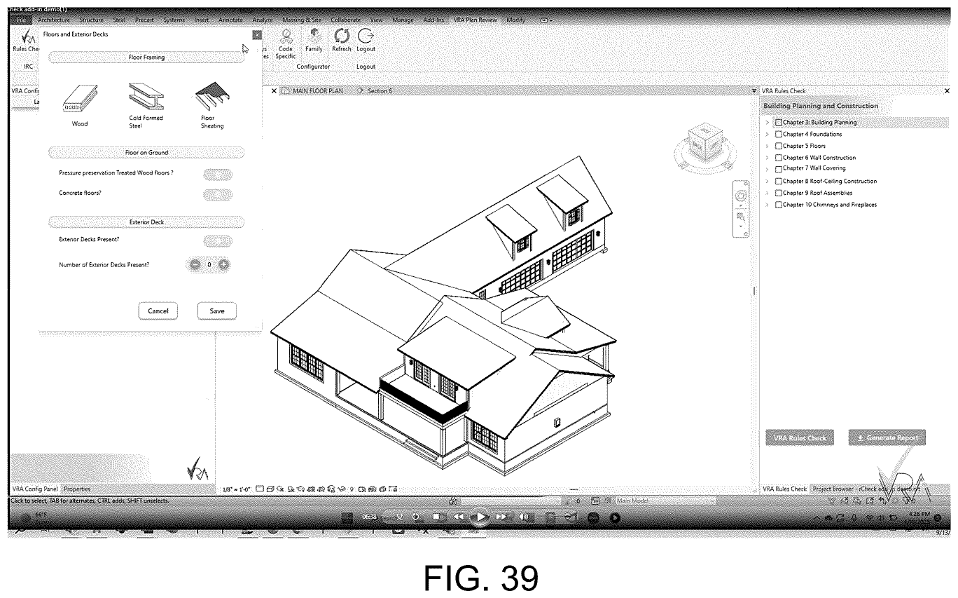

Referring now to FIG. 38, a project information panel stores information about a project involving the BIM model, such as its foundation type, type of floors and decks, type of walls, type of roofs, etc. Each ribbon or icon in this panel represents a specific chapter of a building code section, such as the FBCR code. For example, Chapter 4 of the FBCR is directed about foundations, and chapter 5 is directed to floors, and so on. These ribbons or icons are used to streamline the code check process. Although the model code check interface tool plug-in/add-in is capable to detect all of these characteristics from the model itself and perform a compliance code check, there may be thousands of line items from the FBCR code that need to be tested. Thus, by giving the correct information in advance, the testing process can be streamlined and performed more quickly. Accordingly, FIG. 39 shows a user interface for inputting floor and deck information for a building information model.

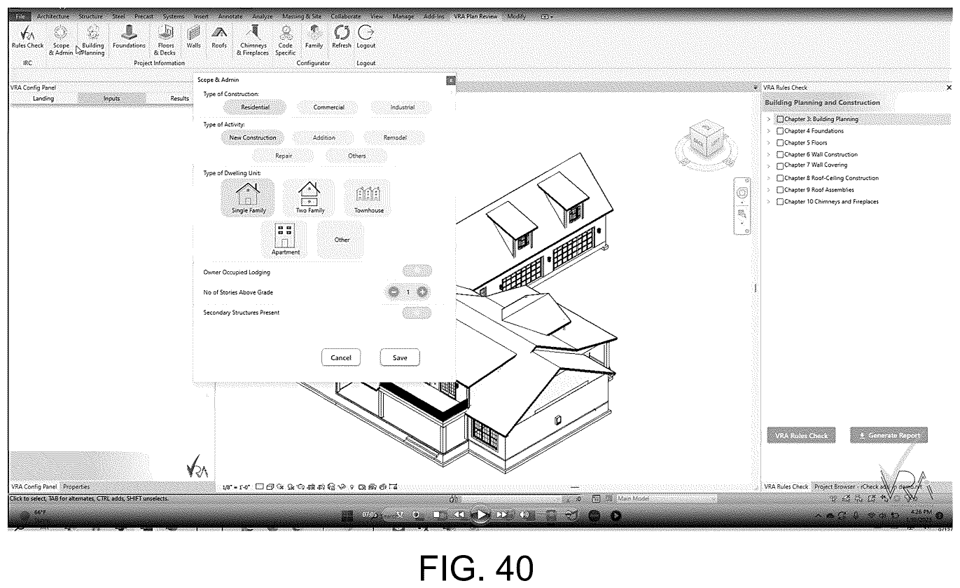

In various embodiments, if a user clicks or selects the Scope & Admin ribbon on the project information panel, a new window pops up where the user can provide information regarding the classification of a project, as shown in FIG. 40, where type of construction, the type of activity, the type of dwelling unit, etc. can be input. With these selections and narrowing of the scope of the projection, the amount of potential building code sections that need to be considered are significantly reduced. Thus, certain chapters and sections of the building code can be disabled that do not deal with a particular project, thereby streamlining and increasing the efficiency of a compliance code check.

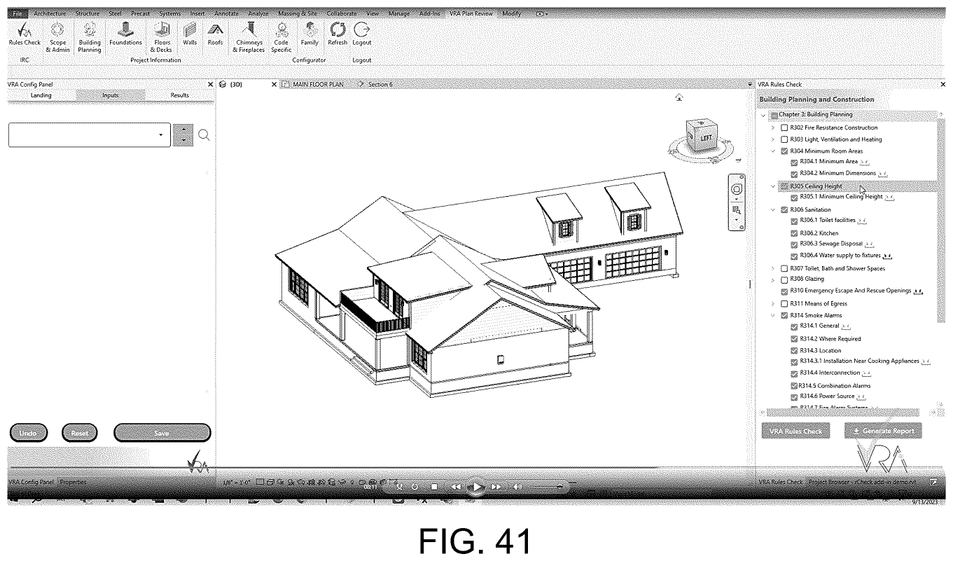

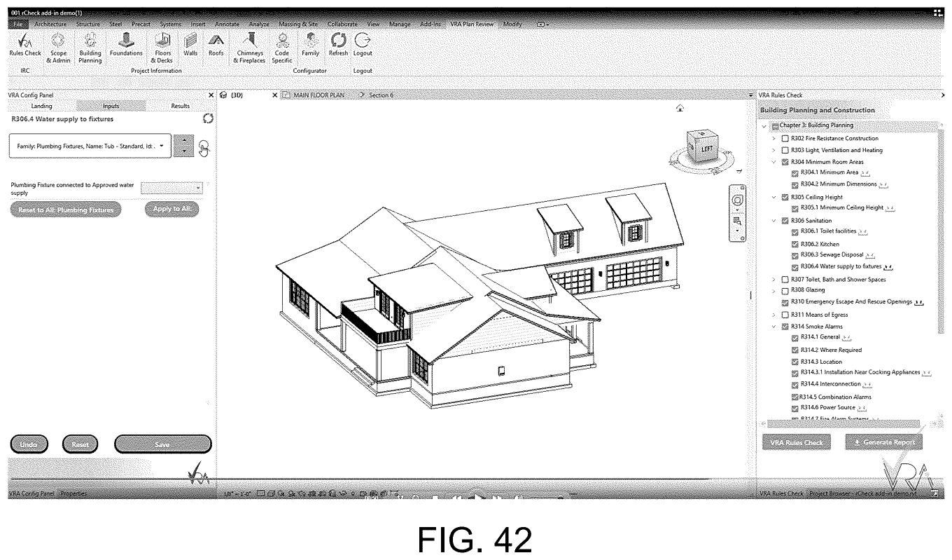

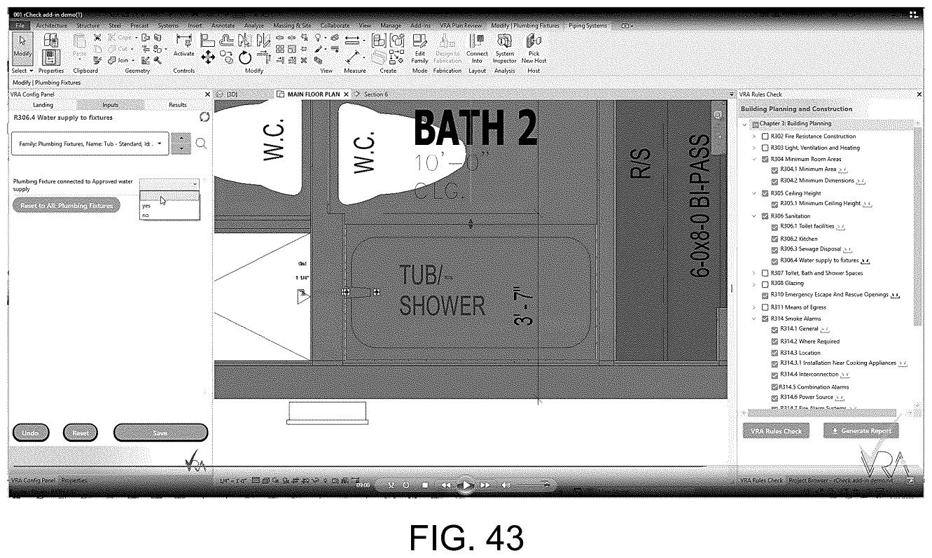

In various embodiments, when the user is ready to perform the compliance code check, the BIM is opened using the Model viewer application 115 and then the user selects the code sections that the user wants to test using the model code check interface tool 110, as illustrated in FIG. 41. The input icons next to code sections will be highlighted that need further input information and the input icons will be grayed out (or not highlighted) that do not need further input information. Accordingly, a user can monitor the input icons to check if they are active or grayed out. If they are active, the user can select them which causes an input configurator interface to be displayed with prompts or questions for the user to provide additional input information, as shown in FIG. 42. For the sections 306.4 and 310, we can see the input icon is not grayed out and if we select them a couple of questions will pop up in the input configurator interface. Since section 306.4 is about water supply to fixtures, a drop down menu is presented on a left side panel (input configurator) that provides a list of plumbing fixtures and below it, there is a list of questions regarding the element selected in the drop down menu. By selecting the Locate icon (which is shown as a magnifying lens in FIG. 42), the particular element can be displayed on the underlying BIM model, as shown in FIG. 43, before answering the questions regarding it, such as whether the plumbing fixture is connected to an approved water supply.

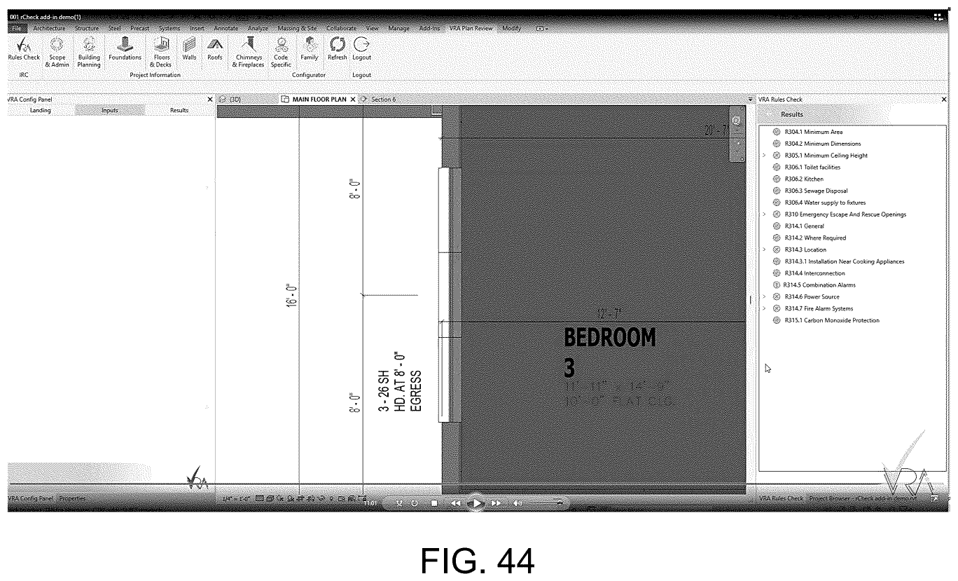

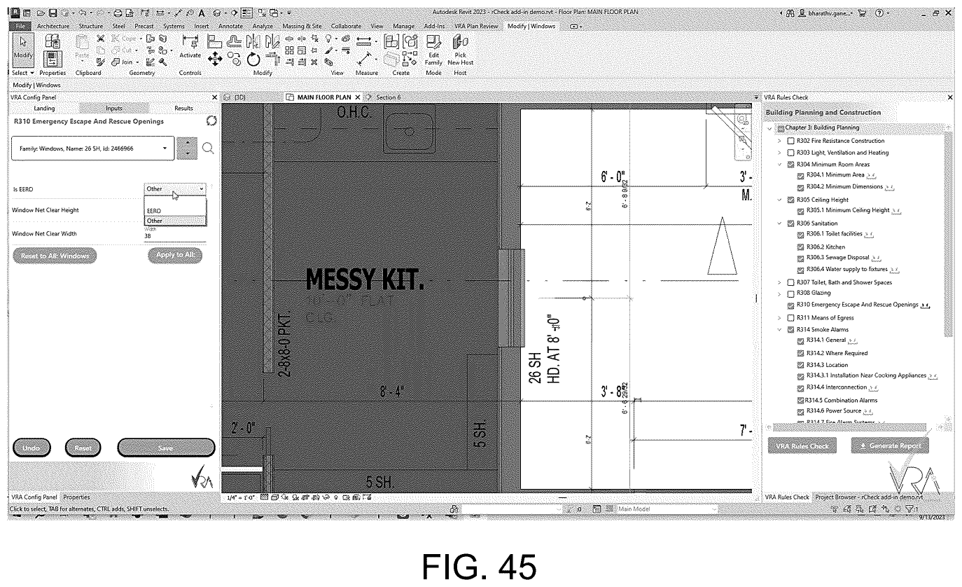

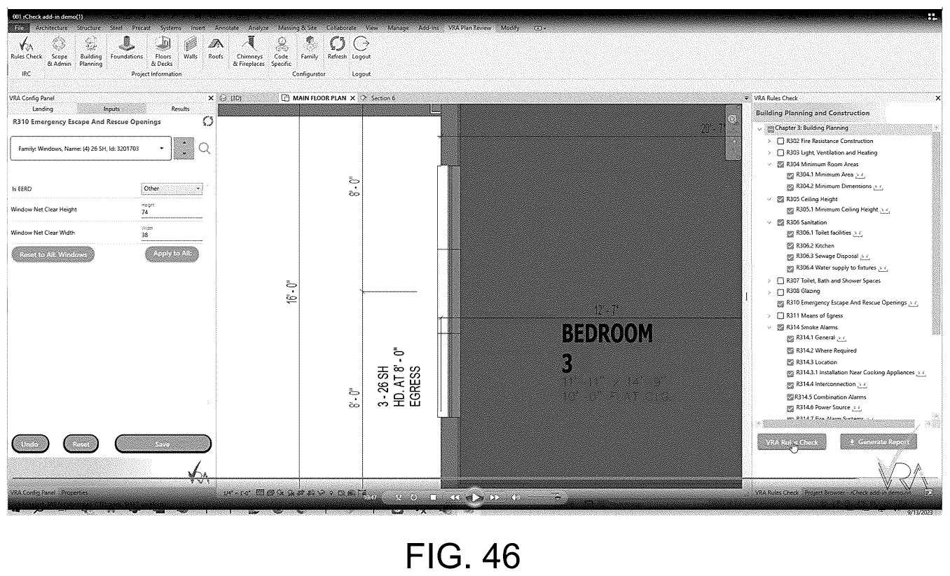

To move to the next element, the up and down arrows may be selected that are positioned next to the drop down menu, as shown in FIG. 44. By using these two arrows, different questions about different families can be answered, and if the same answer applies, an Apply to All button can be selected which can save a lot of time in providing input information. For Section 310 which talks about emergency escape and rescue openings, the rooms can be classified automatically by previously obtained inputs that have been given for the openings present in the model. An opening can be selected from the drop down menu and the Locate button can be selected to see where the particular opening is located in the model, as shown in FIG. 45. In a non-limiting example, a user may be asked if the opening is an EERO (Emergency Escape and Rescue Opening) and this information may not be included in the model, so the user may have to provide the answer, as shown in FIG. 45. Since there may be a lot of windows and doors present in the model, the user may indicate that the opening is not an EERO and select the Apply to All button to categorize each of the openings as an EERO and then select the Save button at the bottom. Thus, while there can be numerous openings in the model, there may be only three to four emergency escape openings, so the user can follow this method to save the time and to individually indicate the EERO designation for the specific emergency escape openings. Alternatively, a tag of the BIM model can be added to a specific opening to indicate that the opening is an EERO and the model code check interface tool may then capture this information automatically and recognize that the opening is an EERO. Once the input information has been completed, the user can select the appropriate button or control (e.g., VRA Rules Check button), as shown in FIG. 46, to perform the compliance code check for the BIM model.

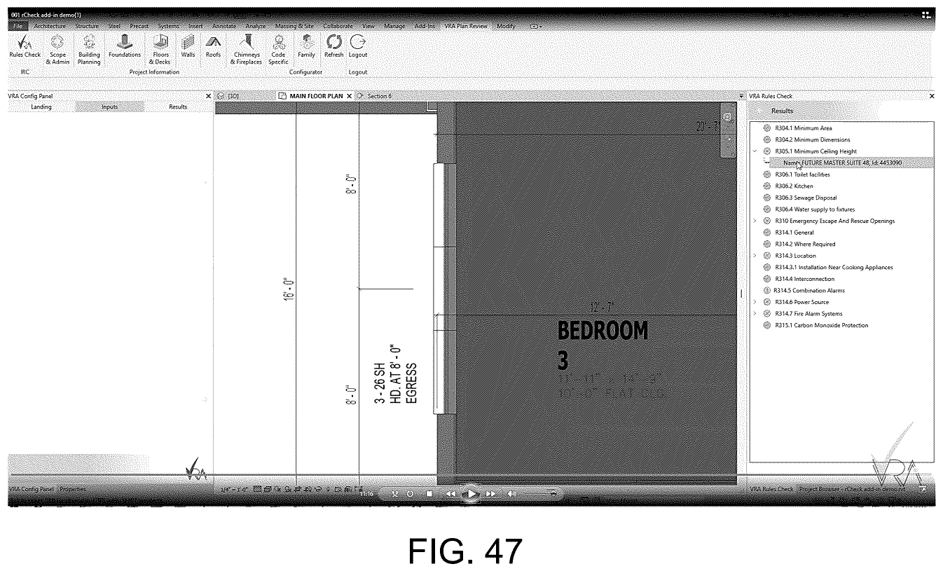

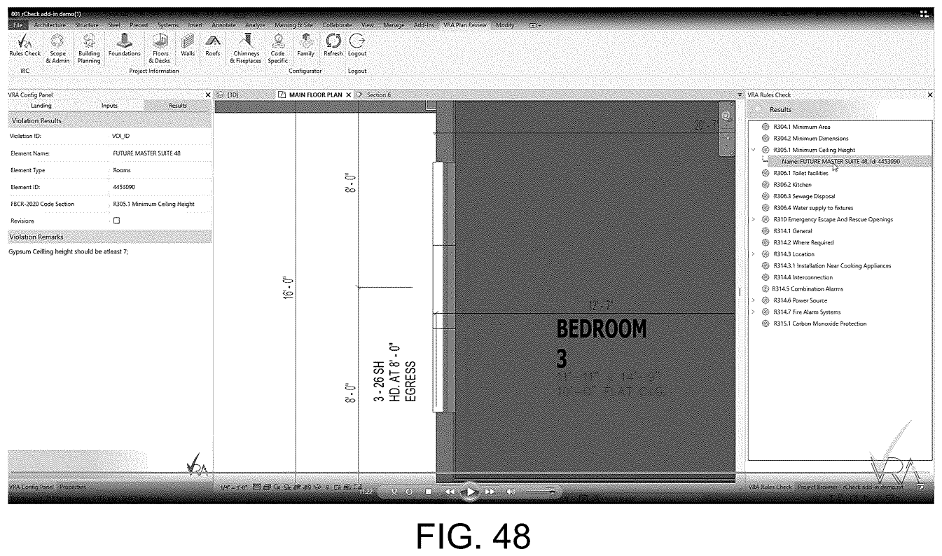

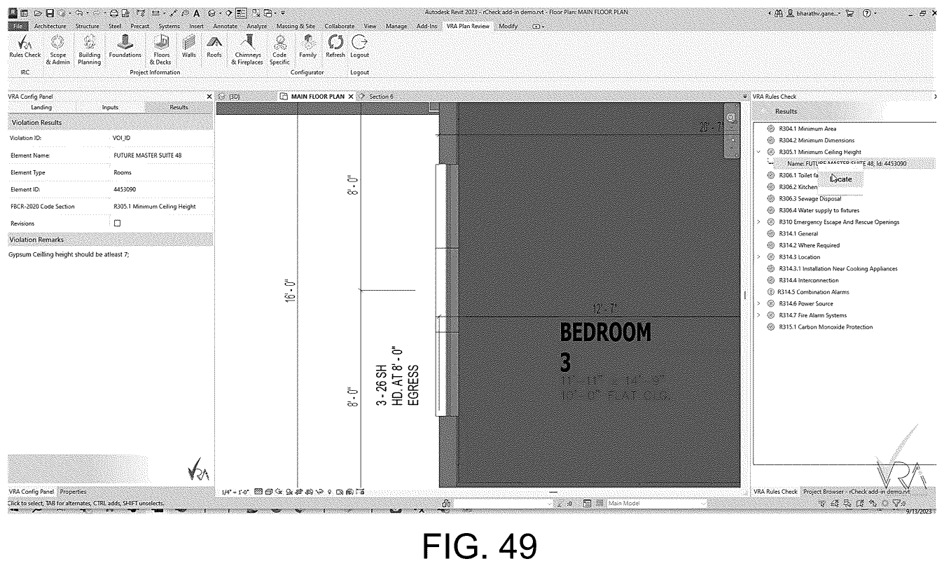

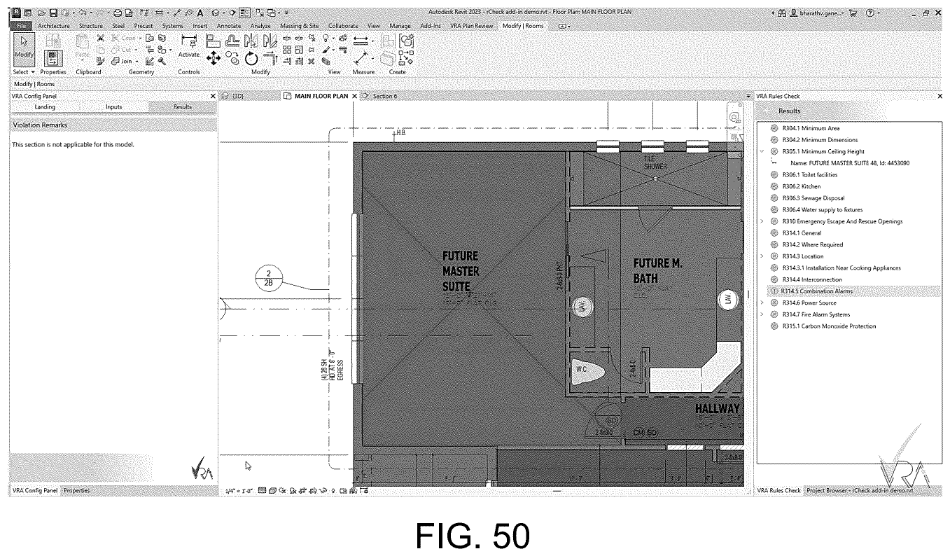

Once the model code check interface tool 110 performs the compliance code check and generates output results, a tick or check mark (or other indicator) is shown next to the code sections (in the code section panel) to which the model is in compliance with and an X or cross mark (or other indicator) is shown next to the code sections to which the model is not in compliance and is in violation of. To learn more about a particular violation, the user can select (e.g., using a left click from a mouse input control or a touch pad) the particular code section and view the model elements or families that are causing the particular violation, as shown in FIG. 47. If the user clicks or selects those item(s), a brief description of the violation is shown on a results panel of the configurator interface, as shown in FIG. 48. In various embodiments, the user can also right click on the item (using a mouse input control or a touch pad) and select a “locate” option to view the elements in the model space, as shown in FIG. 49. For a code section that has an exclamation mark indicator or icon (or other indicator) next to it (as shown in FIG. 50), the code section is indicated to need further evaluation or the section is not applicable for the model.

It should be understood that the described processes may be embodied in one or more software modules that are executed by one or more hardware processors (e.g., processor 120), for example, as the application discussed herein. The described processes may be implemented as instructions represented in source code, object code, and/or machine code. These instructions may be executed directly by hardware processor(s) 120, or alternatively, may be executed by a virtual machine operating between the object code and hardware processors 120. In addition, the disclosed application may be built upon or interfaced with one or more existing systems.

Alternatively, the described processes may be implemented as a hardware component (e.g., general-purpose processor, integrated circuit (IC), application-specific integrated circuit (ASIC), digital signal processor (DSP), field-programmable gate array (FPGA) or other programmable logic device, discrete gate or transistor logic, etc.), combination of hardware components, or combination of hardware and software components. To clearly illustrate the interchangeability of hardware and software, various illustrative components, blocks, modules, circuits, and steps are described herein generally in terms of their functionality. Whether such functionality is implemented as hardware or software depends upon the particular application and design constraints imposed on the overall system. Skilled persons can implement the described functionality in varying ways for each particular application, but such implementation decisions should not be interpreted as causing a departure from the scope of the claims included herein. In addition, the grouping of functions within a component, block, module, circuit, or step is for ease of description. Specific functions or steps can be moved from one component, block, module, circuit, or step to another.

Furthermore, while the processes, described herein, are illustrated with a certain arrangement and ordering of subprocesses, each process may be implemented with fewer, more, or different subprocesses and a different arrangement and/or ordering of subprocesses. In addition, it should be understood that any subprocess, which does not depend on the completion of another subprocess, may be executed before, after, or in parallel with that other independent subprocess, even if the subprocesses are described or illustrated in a particular order.

A manual design review process is time-consuming, error-prone, subjective, and becoming very costly to sustain. Reasons behind these issues include: (a) increase rate of updates of regulations and standards with new knowledge and research outcomes; (b) new, state of the art technologies, equipment, and devices; and (c) a higher amount of data and its multidisciplinary nature (Nawari, 2012a; Nawari and Alsaffar, 2017 and 2017).

In order to perform a code compliance check, applicable codes and regulations must undergo an interpretation process where the semantic structure of each regulation is translated into object rules or parametric models, using certain formal languages, and associated with the land development permit application file data being examined. This data can then be compared to the rules and models, or stated another way the rules and model can be applied to the data, and deficiencies noted. In an non-limiting example, the BIM model defines objects as parameters and relations to other objects and carrying object attributes that specify pertinent details about the objects. For example, the BIM model can include spatial relationships of a design, quantities and properties, and a wide range of details that can be checked against applicable codes, ordinances, and regulations. In various embodiments, parameter input data ingested using the model code check interface tool 110 is supplied to a validation engine of the model code check interface tool 110 which checks the input data against relevant codes and regulations. Outputs of the validation engine can also be provided to an external system.

Certain embodiments of the present disclosure can be implemented in hardware, software, firmware, or a combination thereof. In various embodiments, such software or firmware is stored in computer-readable medium (e.g., a memory) and that is executed by a suitable instruction execution system. In various embodiments, such hardware can be implemented with any or a combination of the following technologies, which are all well known in the art: discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

In the context of this document, a “computer-readable medium” can be any means that can contain, store, communicate, or transport the program for use by or in connection with the instruction execution system, apparatus, or device. The computer readable medium can be, for example but not limited to, an electronic, magnetic, optical, electromagnetic, infrared, or semiconductor system, apparatus, or device. More specific examples (a nonexhaustive list) of the computer-readable medium would include the following: an electrical connection (electronic) having one or more wires, a portable computer diskette or drive (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical).

The above description of the disclosed embodiments is provided to enable any person skilled in the art to make or use the invention. Various modifications to these embodiments will be readily apparent to those skilled in the art, and the general principles described herein can be applied to other embodiments without departing from the spirit or scope of the present disclosure. Thus, it is to be understood that the description and drawings presented herein represent various embodiments, including a presently preferred embodiment, of the invention and are therefore representative of the subject matter which is broadly contemplated by the present disclosure. It is further understood that the scope of the present disclosure fully encompasses other embodiments that may become obvious to those skilled in the art and that the scope of the present disclosure is accordingly not limited.

What is claimed is:

1. A method comprising:
obtaining, using at least one hardware processor, a construction model of a construction project, wherein the construction model includes a plurality of construction project parameters;
obtaining, using the at least one hardware processor, an input specifying a regulatory building code section;
performing, using at least one hardware processor, a compliance code check for the construction model against the regulatory building code section by:
capturing one or more of the construction model parameters from the construction model;
prompting a user to provide one or more additional construction model parameters that is not included in the construction model; and
evaluating the construction model against the regulatory building code section using the captured construction model parameters and the additional construction model parameters; and
outputting, using the at least one hardware processor, a list of model elements included in the construction model, wherein a result of the compliance code check for a model element in the list is indicated next to the model element, wherein selection of the model element causes a location of the model element to be displayed within the construction model.

2. The method of claim 1, wherein the construction model comprises a Building Information Model.

3. The method of claim 1, wherein the construction model comprises a Computer-Aided Design model.

4. The method of claim 1, wherein the regulatory building code section comprises provisions of the Florida Building Code Residential.

5. The method of claim 1, wherein the regulatory building code section comprises provisions of the International Residential Code.

6. The method of claim 1, further comprising capturing, using the at least one hardware processor, one or more of the construction model parameters from manufacturer data associated with the model element.

7. The method of claim 1, further comprising overlaying, using the at least one hardware processor, an input configuration interface over a model viewer application that is configured to display the construction model, wherein the input configuration interface is configured to graphically display prompts for the prompting of the user to provide the one or more additional construction model parameters that is not included in the construction model.

8. The method of claim 7, further comprising overlaying, using the at least one hardware processor, a code section interface that is configured to display the regulatory building code section and is configured to select certain provisions of the regulatory building code section for checking against the construction model.

9. The method of claim 1, further comprising graphically displaying, using the at least one hardware processor, a semi-transparent interface embedded with one or more buttons for initiating an action of compliance code checking.

10. A system comprising:
at least one hardware processor; and
one or more software modules that are configured to, when executed by the at least one hardware processor:
obtain a construction model of a construction project, wherein the construction model includes a plurality of construction project parameters;
obtain an input specifying a regulatory building code section;
perform a compliance code check for the construction model against the regulatory building code section by:
capture one or more of the construction model parameters from the construction model;
prompt a user to provide one or more additional construction model parameters that is not included in the construction model; and
evaluate the construction model against the regulatory building code section using the captured construction model parameters and the additional construction model parameters; and
output a list of model elements included in the construction model, wherein a result of the compliance code check for a model element in the list is indicated next to the model element, wherein selection of the model element causes a location of the model element to be displayed within the construction model.

11. The system of claim 10, wherein the construction model comprises a Building Information Model.

12. The system of claim 10, wherein the construction model comprises a Computer-Aided Design model.

13. The system of claim 10, wherein the regulatory building code section comprises provisions of the Florida Building Code Residential.

14. The system of claim 10, wherein the regulatory building code section comprises provisions of the International Residential Code.

15. The system of claim 10, wherein the one or more software modules are further configured to, when executed by the at least one hardware processor, capture one or more of the construction model parameters from manufacturer data associated with the model element.

16. The system of claim 10, wherein the one or more software modules are further configured to, when executed by the at least one hardware processor, overlay an input configuration interface over a model viewer application that is configured to display the construction model, wherein the input configuration interface is configured to graphically display prompts for the prompting of the user to provide the one or more additional construction model parameters that is not included in the construction model.

17. The system of claim 16, wherein the one or more software modules are further configured to, when executed by the at least one hardware processor, overlay a code section interface that is configured to display the regulatory building code section and is configured to select certain provisions of the regulatory building code section for checking against the construction model.

18. The system of claim 16, wherein the one or more software modules are further configured to, when executed by the at least one hardware processor, display a semi-transparent interface embedded with one or more buttons for initiating an action of compliance code checking.

19. A non-transitory computer-readable medium having instructions stored therein, wherein the instructions, when executed by a processor, cause the processor to:
obtain an input specifying a regulatory building code section;
perform a compliance code check for the construction model against the regulatory building code section by:
capture one or more of the construction model parameters from the construction model;
prompt a user to provide one or more additional construction model parameters that is not included in the construction model; and
evaluate the construction model against the regulatory building code section using the captured construction model parameters and the additional construction model parameters; and
output a list of model elements included in the construction model, wherein a result of the compliance code check for a model element in the list is indicated next to the model element, wherein selection of the model element causes a location of the model element to be displayed within the construction model.

20. The non-transitory computer-readable medium of claim 19, wherein the instructions, when executed by the processor, cause the processor to overlay an input configuration interface over a model viewer application that is configured to display the construction model, wherein the input configuration interface is configured to graphically display prompts for the prompting of the user to provide the one or more additional construction model parameters that is not included in the construction model; and overlay a code section interface that is configured to display the regulatory building code section and is configured to select certain provisions of the regulatory building code section for checking against the construction model.
